(19) United States
(12) Patent Application Publication
(10) Pub. No.: US 2017/0161075 A1
(43) Pub. Date: Jun. 8, 2017

(54) INCREASING PROCESSOR INSTRUCTION WINDOW VIA SEPERATING INSTRUCTIONS ACCORDING TO CRITICALITY

(71) Applicant: Intel Corporation, Santa Clara, CA (US)

(72) Inventors: ALEXANDR TITOV, Severodvinsk (RU); DMITRY M. MASLENNIKOV, Moscow (RU); SERGEY Y. SHISHLOV, Moscow (RU); SERGEY P. SCHERBININ, Obninsk (RU); VALENTIN A. BUROV, Moscow (RU); RON GABOR, Hertzliya (IL); DENIS G. MOTIN, Moscow (RU); OLEG SHIMKO, Khimky (RU); KAMIL GARIFULLIN, Moscow (RU); ALEXANDER V. BUTUZOV, Moscow (RU); EVGENIY N. PODKORYTOV, Dolgoprudny (RU); ANDREY CHUDNOVETS, Moscow (RU)

(21) Appl. No.: 15/021,442

(22) PCT Filed: Jun. 1, 2015
(86) PCT No.: PCT/IB2015/001148

§ 371 Date: Mar. 11, 2016

(51) Int. Cl. G06F 9/38; G06F 9/44; G03F 7/00; G06F 9/30; G03F 1/36; G03F 1/70

(52) U.S. Cl. CPC G06F 9/38; G03F 1/36; G03F 1/70; G03F 7/0005; G06F 9/30003; G06F 9/3017; G06F 9/44

(57) ABSTRACT

In an embodiment, a processor includes a plurality of cores. Each core may include strand logic to, for each strand of a plurality of strands, fetch an instruction group uniquely associated with the strand, wherein the instruction group is one of a plurality of instruction groups, wherein the plurality of instruction groups is obtained by dividing instructions of an application program according to instruction criticality. The strand logic may also be to retire the instruction group in an original order of the application program. Other embodiments are described and claimed.

### FIELD OF INVENTION

Embodiments relate generally to the scheduling of instructions for execution in a computer system.

### BACKGROUND

In a traditional computer processor, each instruction executed by the processor may involve various operations or stages. For example, one operation may be the instruction fetch to retrieve an instruction from memory for additional operations (e.g., decoding, execution, etc.). Each of these operations may require some clock cycles of the processor, and may thus limit the performance of the processor. Some processors may include techniques to improve the number of instructions that are processed during each clock cycle. For example, such techniques may include superscalar processing, instruction pipelining, speculative execution, and so forth.

### BRIEF DESCRIPTION OF THE DRAWINGS

FIG. 1A is a block diagram of an example system in accordance with one or more embodiments.

FIGS. 1B-1C are examples of processing strands in accordance with one or more embodiments.

FIG. 1D is an example of a window buffer in accordance with one or more embodiments.

FIGS. 1E-1F are examples of a window buffer in accordance with one or more embodiments.

FIG. 2 is a sequence in accordance with one or more embodiments.

FIG. 3 is a block diagram of a micro-architecture of a processor core in accordance with one or more embodiments.

FIG. 4A is a block diagram of a portion of a system in accordance with one or more embodiments.

FIG. 4B is a block diagram of a multi-domain processor in accordance with one or more embodiments.

FIG. 4C is a block diagram of a processor in accordance with one or more embodiments.

FIG. 5 is a block diagram of a processor including multiple cores in accordance with one or more embodiments.

FIG. 6 is a block diagram of a micro-architecture of a processor core in accordance with one or more embodiments.

FIG. 7 is a block diagram of a micro-architecture of a processor core in accordance with one or more embodiments.

FIG. 8 is a block diagram of a micro-architecture of a processor core in accordance with one or more embodiments.

FIG. 9 is a block diagram of a processor in accordance with one or more embodiments.

FIG. 10 is a block diagram of a representative SoC in accordance with one or more embodiments.

FIG. 11 is a block diagram of another example SoC in accordance with one or more embodiments.

FIG. 12 is a block diagram of an example system with which one or more embodiments can be used.

FIG. 13 is a block diagram of another example system with which one or more embodiments may be used.

FIG. 14 is a block diagram of a computer system in accordance with one or more embodiments.

FIG. 15 is a block diagram of a system in accordance with one or more embodiments.

### DETAILED DESCRIPTION

In a typical superscalar processor, multiple instructions are dispatched simultaneously to different functional units of the processor. The superscalar processor may process instructions in threads. As used herein, the term “thread” refers to a sequence of related instructions that are data-dependent upon each other, and which are executed to carry out a particular task. Some superscalar processors may use in-order execution, meaning that each instruction in a thread is executed in the order that instructions are found as programmed in source code (i.e., in “program order”). In contrast, superscalar processors using out-of-order execution (referred to as “out-of-order superscalar processors”) may execute the instructions of a thread in an order that is determined by the availability of input data, rather than by their original program order.

Further, in a typical superscalar processor, the instructions are fetched in program order. Data related to these instructions can be stored in buffers during an execution window (referred to herein as “window buffers”). Examples of window buffers include a load instruction buffer, a store instruction buffer, a reorder buffer, and so forth. The instructions may be retired or removed from the window buffers in program order. As such, the maximum distance in the flow of instructions between the oldest instruction that is not yet completed and the newest instruction that has already started execution (referred to as the “instruction scheduling window”) can be related to the number of entries in the window buffers.

In accordance with some embodiments, threads can be divided into N separate processing strands. As used herein, the term “strand” refers to a subset of instructions of a thread that are grouped according to instruction criticality. An N-way processor core can include N separate processing paths or “ways,” with each way including separate hardware components for processing strands of a particular level of criticality. In some embodiments, a window buffer of the N-way core can be divided into N partitions, with each partition of the window buffer being allocated to strands of a particular level of criticality. By processing instructions in separate strands according to criticality, some embodiments may enable a larger instruction scheduling window without expanding the physical size of the window buffer.

Although the following embodiments are described with reference to particular implementations, embodiments are not limited in this regard. In particular, it is contemplated that similar techniques and teachings of embodiments described herein may be applied to other types of circuits, semiconductor devices, processors, systems, etc. For example, the disclosed embodiments may be implemented in any type of computer system, including server computers (e.g., tower, rack, blade, micro-server and so forth), communications systems, storage systems, desktop computers of any configuration, laptop, notebook, and tablet computers (including 2:1 tablets, phablets and so forth).

In addition, disclosed embodiments can also be used in other devices, such as handheld devices, systems on chip (SoCs), and embedded applications. Some examples of handheld devices include cellular phones such as smartphones, Internet protocol devices, digital cameras, personal digital assistants (PDAs), and handheld PCs. Embedded applications may typically include a microcontroller, a digital signal processor (DSP), network computers (NetPC), set-top boxes, network hubs, wide area network (WAN) switches, wearable devices, or any other system that can perform the functions and operations taught below. Further, embodiments may be implemented in mobile terminals having standard voice functionality such as mobile phones, smartphones and phablets, and/or in non-mobile terminals without a standard wireless voice function communication capability, such as many wearables, tablets, notebooks, desktops, micro-servers, servers and so forth.

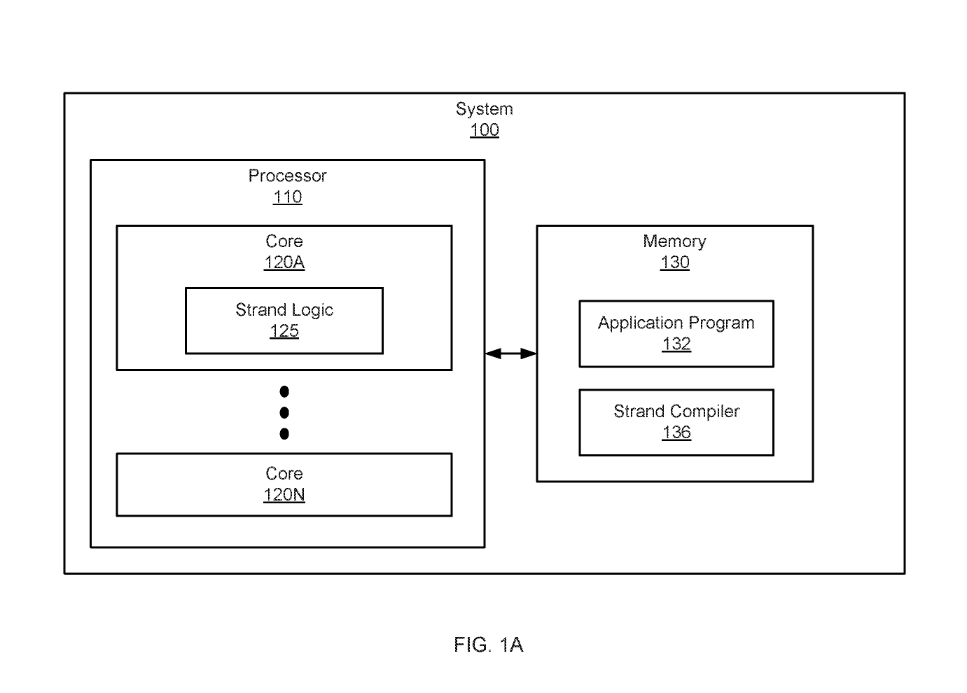

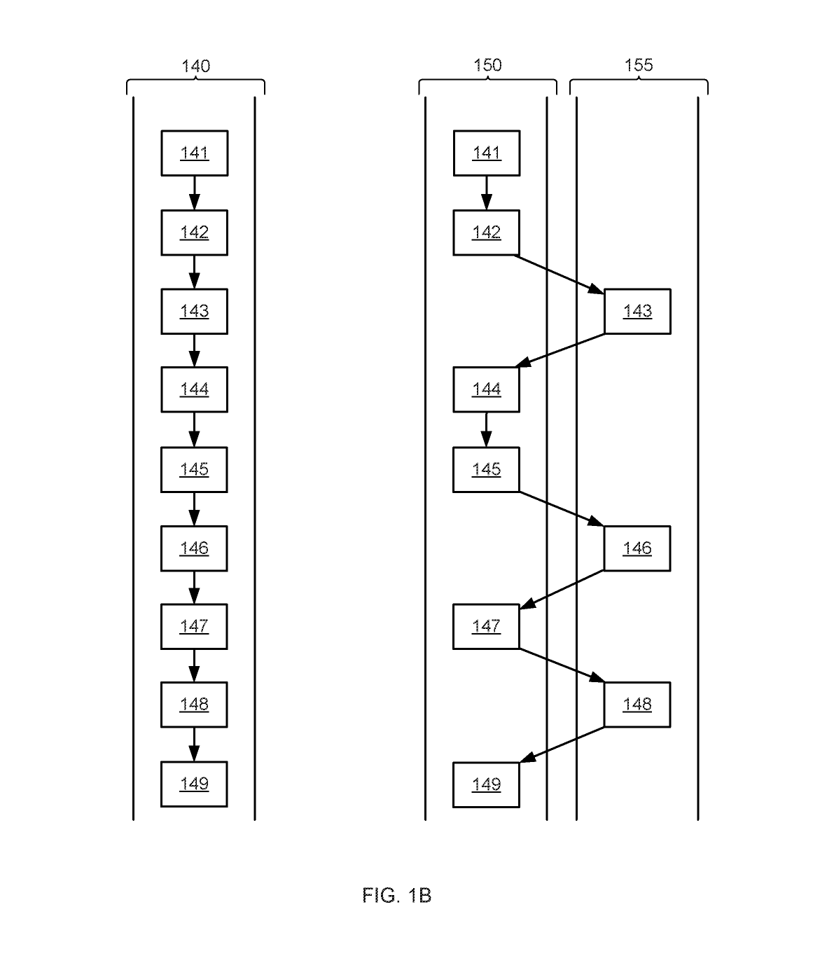

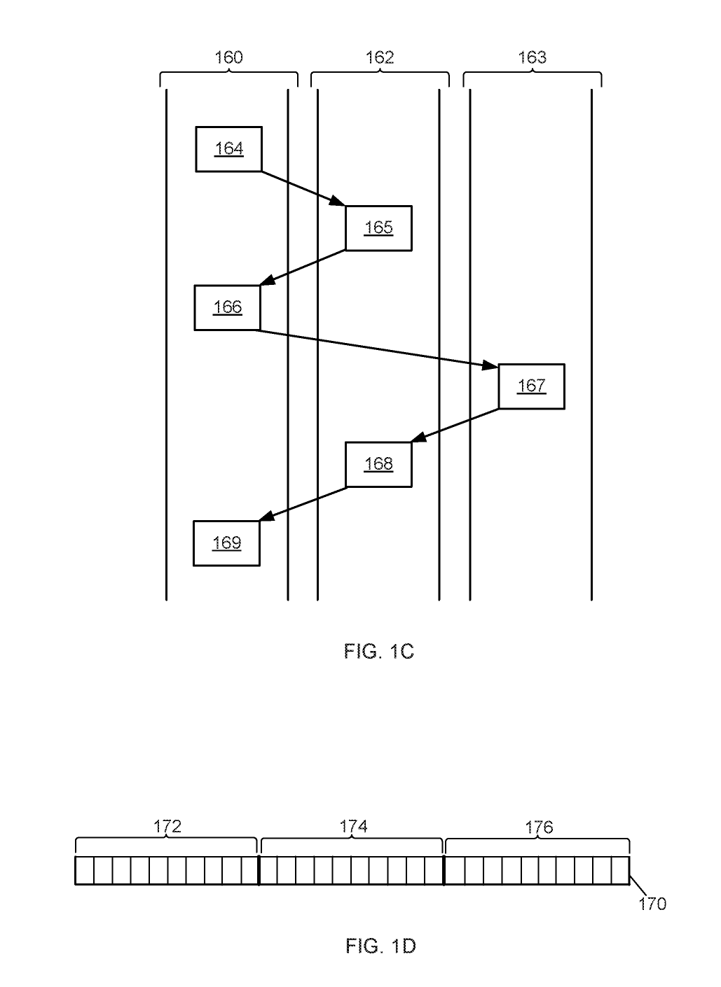

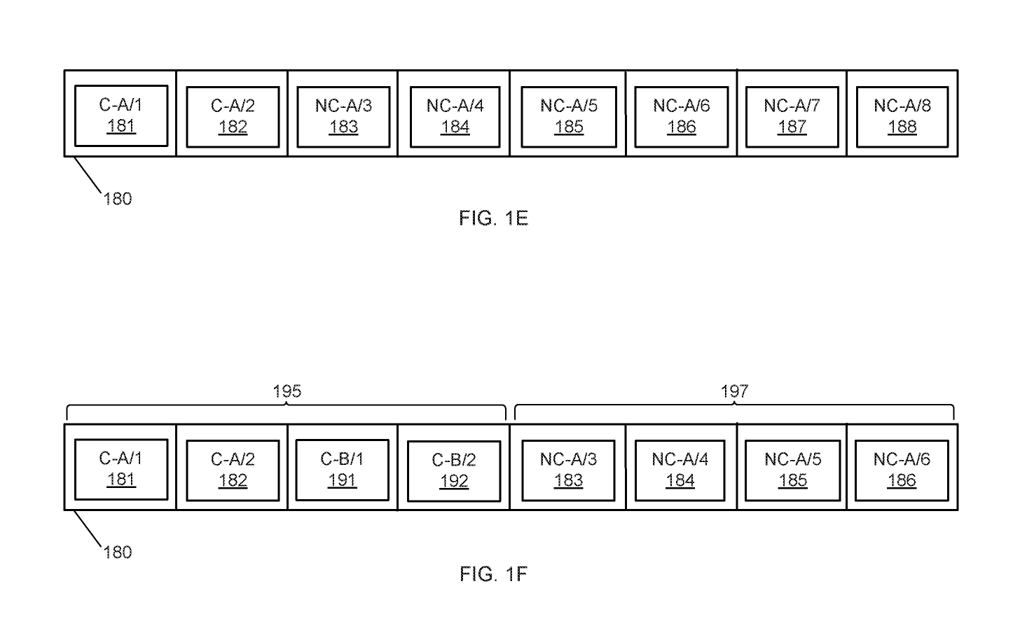

Referring now to FIG. 1A, shown is a block diagram of an example system 100 in accordance with one or more embodiments. In some embodiments, the system 100 may be an electronic device or component. For example, the system 100 may be a cellular telephone, a computer, a server, a network device, a system on a chip (SoC), a controller, a wireless transceiver, a power supply unit, a blade computer, etc.

The system 100 may include a processor 110 coupled to memory 130. The memory 130 may be any type of computer memory including dynamic random access memory (DRAM), static random-access memory (SRAM), non-volatile memory (NVM), a combination of DRAM and NVM, etc. As shown, in some embodiments, the memory 130 may include a application program 132 and a strand compiler 136. The processor 110 may be a general purpose hardware processor such as a central processing unit (CPU). The processor 110 may include any number of processing cores 120A-120N (referred to collectively as “cores 120”). In some embodiments, each core 120 may include strand logic 125. The strand logic 125 may be implemented in hardware, firmware, software, and/or any combination thereof.

The processor 110 may execute the strand compiler 136 and the application program 132. In some embodiments, the strand compiler 136 can analyze and/or compile the application program 132. For example, the strand compiler 136 may be a binary compiler or recompiler which transforms the binary code of the application program 132 during execution (i.e., at program execution time). Further, the strand compiler 136 may analyze the instructions of the application program 132, and may determine a criticality for each instruction. As used herein, the criticality of an instruction refers to a measure or indication of the impact that the delay of the instruction can have on the total execution time of the program. For example, in some embodiments, the criticality of an instruction may be expressed as a numerical score, with the absolute value of the score equal to the maximum number of clock cycles for which allocation of the instruction can be delayed without increasing the total execution time of the program. In some embodiments, the strand compiler 136 may determine the criticality of each instruction based on historical data of previous executions of instructions, profiling run(s) of the application program 132, static analysis of the application program 132, and so forth.

In some embodiments, the strand compiler 136 may determine the latency of each instruction and the dependencies between instructions, and may use this information to estimate the criticality of each instruction in the application program 132. For example, the strand compiler 136 may identify instructions with long-latency as instructions with high criticality. Further, the strand compiler 136 may identify instructions on which long-latency instructions depend as instructions with high criticality. Based on estimated criticality of each instruction, the strand compiler 136 may assign the instruction to only one group of N groups, where N is the number of ways in each core 120. For example, for a core 120 with N=2 ways, the strand compiler 136 may assign each instruction of the application program 132 to either a group with high criticality or a group with low criticality. In another example, for N=4, the strand compiler 136 may assign each instruction of the application program 132 to one of four groups corresponding to very high criticality, moderately high criticality, moderately low criticality, and very low criticality. In some embodiments, the strand compiler 136 may compile the program instructions to execute in strands based on the criticality group of level of each instruction. Further, the strand compiler 136 may compile the program into binary code that includes information indicating the assigned strand, group and/or the criticality level of each instruction. For example, strand compiler 136 may set a field or other identifier of the compiled instruction, may insert one or tags associated with the instruction into the binary code, and/or may set a data structure or register to indicate the strand, group and/or level of each instruction.

In some embodiments, the strand compiler 136 may assign different amounts or percentages of instructions to each group based on the criticality of the group. Further, in some embodiments, the amount or percentage of instructions assigned to each group is larger as the criticality of the group decreases. For example, for a core 120 with N=2 ways, a high-criticality group may include 10% of instructions, and a low-criticality group may include 90% of instructions. In some embodiments, the instructions may be moved in the memory address space such that instructions of each group are placed locally, thereby facilitating the fetching of instructions in a single group by a separate strand in the program order within the strand.

In some embodiments, the strand compiler 136 may transform the application program 132 to handle register and memory dependencies across instruction groups and/or strands. For example, if an instruction in a first strand writes a value to a register, and an instruction in a second strand requires the value, the first strand and/or the second strand may be compiled to such that the instruction in the second strand can read the value written to the register. In some embodiments, the strand compiler 136 may insert a first tag into the binary code to identify each instruction producing a register value to be consumed by a different strand. Further, the strand compiler 136 may also insert a second tag in the different strand to identify the instruction that will consume the register value.

In another example, in the case of an instruction accessing a specific memory location, it can be necessary to check for a different instruction for the same memory location that is earlier in the program order for the entire program (i.e., across all strands), and which has not completed yet. Such checking may involve reading the store queue and the load queue to identify instructions of any strand that access the same memory address. Further, this checking may involve comparing the original program order of these instructions to determine which instruction is older. Note that, while examples of techniques for handling cross-strand data dependencies are discussed above, it is contemplated that any other suitable technique may be used.

In some embodiments, the strand compiler 136 may transform the instructions to indicate the original program order of the application program 132. To indicate the program order between instructions assigned to the same strand, the strand compiler 136 may allocate instructions in memory in such a way that the mutual order in which instructions appear in the control flow of the strand is the program order. In some embodiments, to indicate the program order between instructions assigned to different strands, the strand compiler 136 may append each instruction with a field or other indicator of the original program order. Further, in some embodiments, the strand compiler 136 may insert markers into the binary code to indicate the program order of instructions. For example, in the case of two strands, the instructions may be preceded or followed by “flip” markers to indicate a switch to/from the other strand. Furthermore, the original program order of the instructions may be determined or indicated using any other suitable mechanism.

In some embodiments, the cores 120 may process the application program 132 using the strand logic 125. For example, the strand logic 125 may include a multitude of instruction pointers, where each instruction pointer corresponds to one of the multiple processing ways of the core 120 and indicates the next instruction to fetch from the strand associated with the corresponding processing way. Instructions of each strand may be fetched using the corresponding instruction pointers, which get updated according to the control flow of the strand. As a result, the order in which instructions of a strand are fetched is the program order of the original application. In some embodiments, no restriction is imposed on the mutual order between fetching instructions assigned to different strands. Further, in some embodiments, the strand logic 125 may be partially shared with the simultaneous multithreading (SMT) mode control logic. For example, the instruction pointers may be used for fetching a multitude of single-strand threads simultaneously in the SMT mode. Each strand may be executed in one of the N ways of the core 120.

Referring now to FIG. 1B, shown is an example using two processing strands in accordance with one or more embodiments. As shown, in the example of FIG. 1B, a thread 140 includes a sequence of instructions 141-149. Assume that, in this example, the thread 140 is to be processed in two strands (e.g., in a two-way processor core). Assume further that the strand compiler 136 (shown in FIG. 1A) assigns instructions 143, 146, and 148 to a first strand and/or group associated with high criticality, and assigns the remaining instructions to a second strand and/or group associated with low criticality. Thus, as shown in FIG. 1B, the strand logic 125 may execute a first strand 150 including the low criticality instructions 141, 142, 144, 145, 147, and 149. Further, the strand logic 125 may also execute a second strand 155 including the high criticality instructions 143, 146, and 148. In some embodiments, the first strand 150 and the second strand 155 may be executed in separate ways of a core 120. In addition, in some embodiments, the instructions in each strand are fetched when the respective way has processing capacity. Furthermore, in some embodiments, the fetching of instructions across all strands may occur out-of-order with respect to the original program order.

Referring now to FIG. 1C, shown is an example using three processing strands in accordance with one or more embodiments. Assume that, in the example of FIG. 1C, a thread (not shown) has been divided into three strands that correspond to low, medium, and high criticality. As shown, a first strand 160 includes three low-criticality instructions 164, 166, and 169. Further, a second strand 162 includes two medium-criticality instructions 165 and 168. In addition, a third strand 163 includes one high-criticality instruction 167. In some embodiments, the strand logic 125 may execute the strands 160, 162, and 163 in separate ways of a core 120.

In some embodiments, the strand logic 125 may assign or allocate entries of any window buffers to multiple partitions. Each partition may be allocated to a different processing way in each core 120. For example, referring to FIG. 1D, shown is an example window buffer 170 in accordance with some embodiments. The window buffer 170 may be a physical buffer (e.g., a reorder buffer, a load buffer, a store buffer, etc.) Assume that, in the example of FIG. 1D, the window buffer 170 is included in a core 120 having three processing ways. Accordingly, the entries of the window buffer 170 are mapped into three logical partitions 172, 174, 176. Assume further that the first partition 172 is allocated to low-criticality instructions, the second partition 174 is allocated to medium-criticality instructions, and the third partition 176 is allocated to high-criticality instructions.

In some embodiments, each partition of a window buffer may have the same number of entries, but the percentage of instructions allocated to each criticality group may vary according to criticality. For example, the allocated proportion of instructions can vary inversely with the level of criticality, such that the amount or percentage of instructions assigned to each group is smaller as the criticality of the group increases.

In some embodiments, allocating a larger proportion of a window buffer to higher criticality instructions may expand the effective instruction scheduling window. For example, referring now to FIG. 1E, shown is an example window buffer 180. Assume that, in the example of FIG. 1E, the window buffer 180 is not partitioned according to criticality. Assume further that the window buffer 180 is used by a thread including a repeating loop of eight instructions, with the first two instructions in each iteration of the loop being designated as critical (e.g., with relatively high criticality), and the last six instructions in each iteration of the loop being designated as non-critical (e.g., with relatively low criticality). Thus, as shown in FIG. 1E, the window buffer 180 includes the eight instructions 181-188 which complete a first iteration “A.” For example, the instruction 181 is labeled “C-A/1” to indicate that the first instruction (“1”) of the first iteration (“A”) is designated as critical (“C”). In another example, the instruction 183 is labeled “NC-A/3” to indicate that the third instruction (“3”) of the first iteration (“A”) is designated as non-critical (“NC”).

Referring now to FIG. 1F, shown is an example of the window buffer 180 that is partitioned according to criticality. Specifically, FIG. 1F shows the eight entries of the window buffer 180 as divided equally into a first partition 195 for critical instructions and a second partition 197 for non-critical instructions. As shown, the second partition 197 includes the first four non-critical instructions 183-186 of the first iteration “A.” Further, the first partition 195 includes the two critical instructions 181-182 of the first iteration “A.” However, because the first partition 195 is allocated four entries, the first partition 195 can also include the two critical instructions 191-192 of the second iteration “B” (i.e., the next iteration after iteration “A”). As such, partitioning the window buffer 180 in this manner allows the instruction scheduling window to be extended into the second iteration “B” without increasing the number of entries in the window buffer 180.

Note that the examples shown in FIGS. 1A-1F are provided for the sake of illustration, and are not intended to limit any embodiments. For example, it is contemplated that the window buffers 170, 180 shown in FIGS. 1D-1F may include any number of partitions. In another example, it is contemplated that the percentage of instructions allocated to each criticality group may be equal, and the partitions of a window buffer may be sized according to criticality. In yet another example, it is contemplated that any of the tasks of the strand compiler 136 may also be implemented in hardware (e.g., in the core 120). In still another example, it is contemplated that any of the tasks of the strand logic 125 may also be implemented in software. Further, the system 100 may include different components, additional components, different arrangements of components, and/or different numbers of components than shown in FIG. 1A.

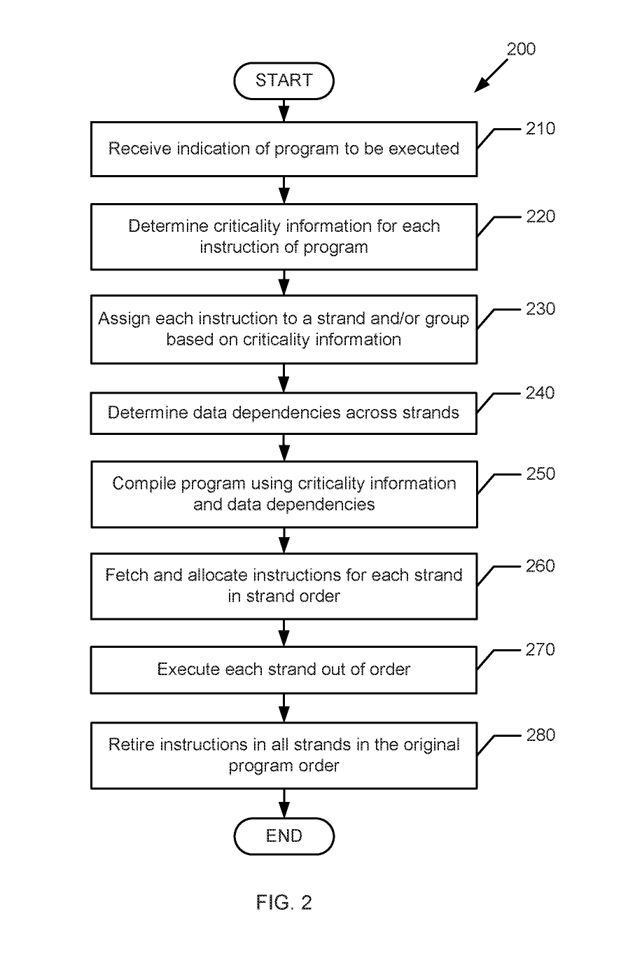

Referring now to FIG. 2, shown is a sequence 200 in accordance with one or more embodiments. In some embodiments, all or a part of the sequence 200 may be implemented by the strand logic 125 and/or the strand compiler 136 shown in FIG. 1A. In some embodiments, some or all of the sequence 200 may be implemented in hardware, software, and/or firmware. In firmware and software embodiments it may be implemented by computer executed instructions stored in a non-transitory machine readable medium, such as an optical, semiconductor, or magnetic storage device. The machine readable medium may store data, which if used by at least one machine, causes the at least one machine to fabricate at least one integrated circuit to perform a method. For the sake of illustration, the steps involved in the sequence 200 may be described below with reference to FIGS. 1A-1F, which show examples in accordance with some embodiments. However, the scope of the various embodiments discussed herein is not limited in this regard.

At block 210, an indication of a program to be executed may be received. For example, referring to FIG. 1A, the strand compiler 136 receives an indication (e.g., a signal, command, etc.) that the application program 132 is to be compiled for execution.

At block 220, criticality information for instructions in the program may be determined. For example, referring to FIG. 1A, the strand compiler 136 determines a criticality score or value for each instruction in the application program 132. In some embodiments, the strand compiler 136 is a binary compiler. For example, the strand compiler 136 may be a re-compiler or binary translator.

At block 230, each instruction may be assigned to an instruction strand and/or group based on the criticality information. Each instruction strand and/or group may be associated with a partition of a window buffer. For example, referring to FIGS. 1A-1D, the strand compiler 136 may divide the instructions of the application program 132 into three different groups, corresponding to three defined levels of criticality. Specifically, the strand compiler 136 may assign instructions 164, 166, and 169 to a low-criticality strand and/or group, may assign instructions 165 and 168 to a medium-criticality strand and/or group, and may assign instruction 167 to a high-criticality strand and/or group. The low-criticality strand and/or group may be associated with the first partition 172 of window buffer 170. Further, the medium-criticality strand and/or group may be associated with the second partition 174, and the high-criticality strand and/or group may be associated with the third partition 176.

At block 240, data dependencies between instruction strands may be determined. For example, referring to FIG. 1A, the strand compiler 136 can determine register and memory dependencies between instructions in the different instruction strands.

At block 250, the program may be compiled using the criticality information and the data dependencies across strands and/or groups. For example, referring to FIG. 1A, the strand compiler 136 compiles the application program 132 into binary form. The compiled program may include information indicating the assigned strand, group and/or the criticality level of each instruction (e.g., tags, fields, identifiers, etc.). Further, the compiled program may include information indicating register and memory dependencies across instruction strands. Further, the compiled program may include information indicating the original program order of some or all of the instructions.

At block 260, instructions may be fetched and allocated for each strand in strand order. As used herein, “strand order” refers to the order of instructions included a given strand, but without serialization across strands. Thus, the instructions can be fetched in order within each individual strand, but can be fetched out of program order with respect to instructions in other strands. For example, referring to FIGS. 1A and 1F, the strand logic 125 can fetch instruction “C-B/1” of second iteration “B” for a critical strand before fetching instruction “NC-A/7” of first iteration “A” for a non-critical strand.

At block 270, each strand may be executed out of order. In some embodiments, a strand can execute instructions out of order with respect to strand order and/or program order. For example, referring to FIGS. 1A and 1F, a first processing way can execute critical instruction “C-B/1” before non-critical instruction “NC-A/7” is executed by a second processing way. In some embodiments, the strand logic 125 may manage cross-strand data dependencies during the execution of the instructions. For example, the strand logic 125 may use tags included in the binary code to identify instructions producing or consuming register values. Further, the strand logic 125 may compare information in the compiled program about the program order of instructions to determine which instruction is to access a memory location.

At block 280, instructions in all strands may be retired in original program order. For example, referring to FIG. 1A, the strand logic 125 can retire instructions in program order. In some embodiments, the strand logic 125 may use information (e.g., tags, bits, etc.) included in the compiled program to determine the program order location of instructions across all current strands. Further, the strand logic 125 may only retire an instruction if it has the earliest program order location of all instructions across the current strands. As such, the instructions can be retired in the original program order, even if they are executed in separate strands. After block 280, the sequence 200 is completed.

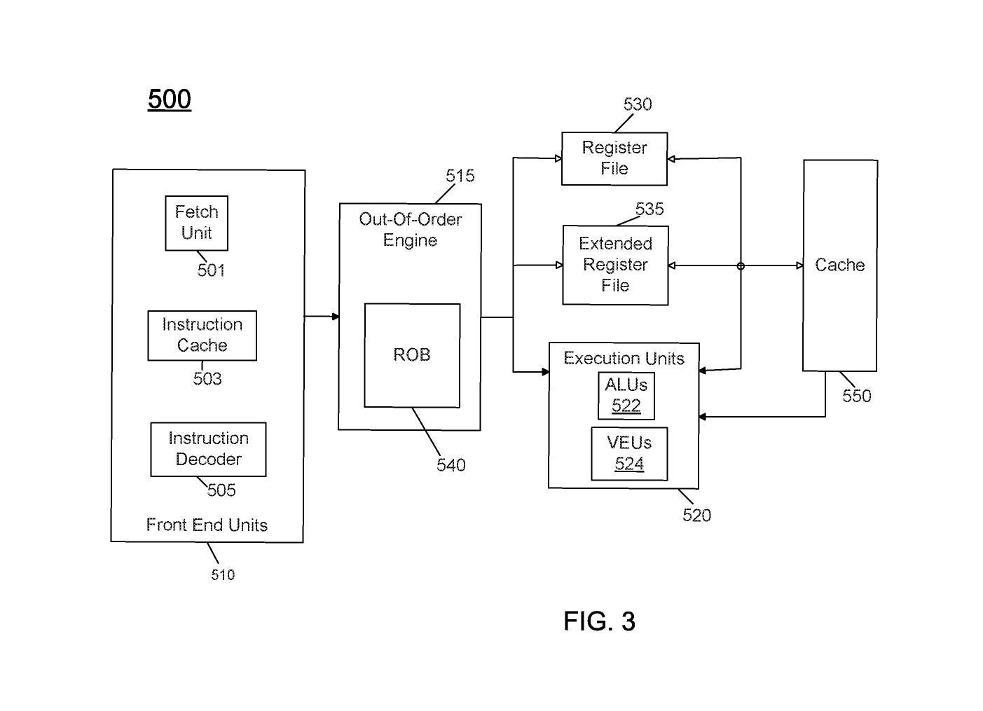

Referring now to FIG. 3, shown is a block diagram of a micro-architecture of a processor core in accordance with one embodiment of the present invention. As shown in FIG. 3, processor core 500 may be a multi-stage pipelined out-of-order processor. Some or all of the components of the processor core 500 may correspond generally to the strand logic 125 (shown in FIG. 1A). In some embodiments, the processor core 500 may include any simultaneous multithreading processor technology (e.g. Hyper-Threading), and may include separate hardware components (e.g., processing ways) for executing multiple threads simultaneously. Further, the processor core 500 may execute multiple strands of a single thread simultaneously.

As shown in FIG. 3, core 500 includes front end units 510, which may be used to fetch instructions to be executed by separate processing strands. For example, front end units 510 may include a fetch unit 501, an instruction cache 503, and an instruction decoder 505. In some implementations, front end units 510 may further include a trace cache, along with microcode storage as well as a micro-operation storage. The fetch unit 501 may fetch instructions for various strands executed in separate ways of the core 500. The instructions may be fetched from memory or instruction cache 503, and may be fed to instruction decoder 505 to decode them into primitives, i.e., micro-operations for execution by the processor.

In some embodiments, the fetch unit 501 may fetch instructions for each strand in strand order. For example, the fetch unit 501 may fetch instructions in order within each individual strand, but may fetch instructions out of program order across other strands.

Coupled between front end units 510 and execution units 520 is an out-of-order (OOO) engine 515 that may be used to receive the micro-instructions and prepare them for execution. The OOO engine 515 may include various buffers to re-order micro-instruction flow and allocate various resources needed for execution. In some embodiments, the buffers of the OOO engine 515 may be divided into multiple partitions, with each partition being allocated to a particular strand and/or instruction group associated with a criticality level.

In some embodiments, the OOO engine 515 may provide renaming of logical registers onto storage locations within various register files such as register file 530 and extended register file 535. Register file 530 may include separate register files for integer and floating point operations. Extended register file 535 may provide storage for vector-sized units, e.g., 256 or 512 bits per register. In some embodiments, the register file 530 and/or the extended register file 535 may be divided into multiple partitions, with each partition being allocated to a particular strand and/or instruction group associated with a criticality level.

Various resources may be present in execution units 520, including, for example, various integer, floating point, and single instruction multiple data (SIMD) logic units, among other specialized hardware. For example, such execution units may include one or more arithmetic logic units (ALUs) 522 and one or more vector execution units (VEUs) 524, among other such execution units.

In some embodiments, the OOO engine 515 may include a reorder buffer (ROB) 540. The ROB 540 may include various arrays and logic to receive information associated with instructions that are executed. In some embodiments, the ROB 540 may be divided into multiple partitions, with each partition being allocated to a particular strand and/or instruction group associated with a criticality level.

In some embodiments, the ROB 540 may determine whether instructions in each strand can be validly retired, and the result data committed to the architectural state of the processor, or whether one or more exceptions occurred that prevent a proper retirement of the instructions. In some embodiments, the ROB 540 may manage cross-strand data dependencies. Further, the ROB 540 may retire instructions across all strands in the original program order. In addition, the ROB 540 may handle any other operations associated with retirement.

As shown in FIG. 3, the ROB 540 may be coupled to a cache 550 which, in one embodiment may be a low level cache (e.g., an L1 cache) although the scope of the present invention is not limited in this regard. Also, execution units 520 can be directly coupled to cache 550. From cache 550, data communication may occur with higher level caches, system memory and so forth. Although FIG. 3 shows a particular example implementation, understand that the scope of various embodiments is not limited by this example.

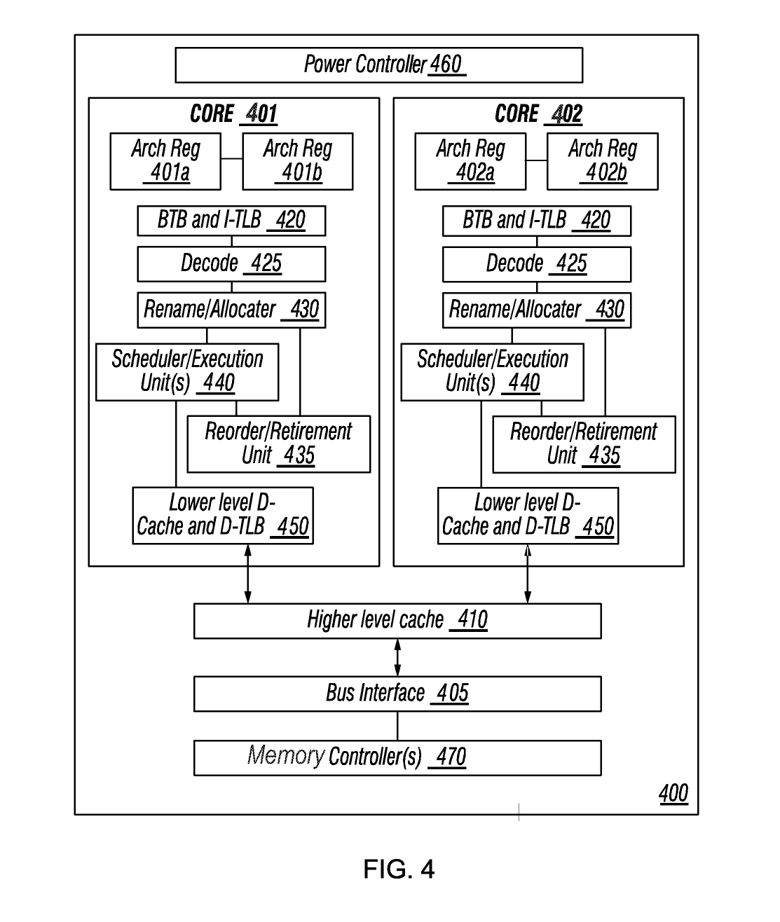

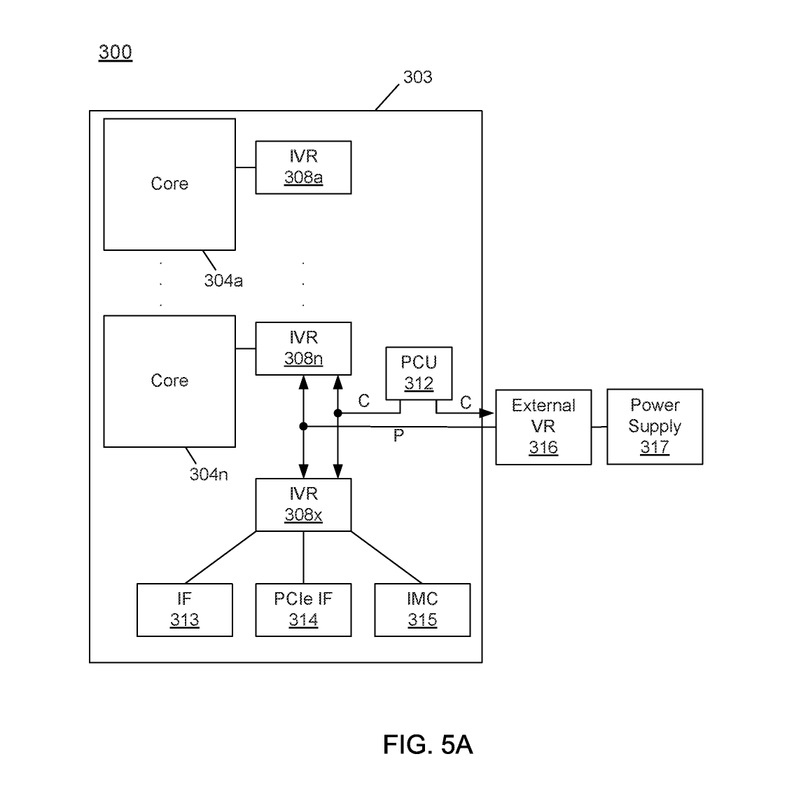

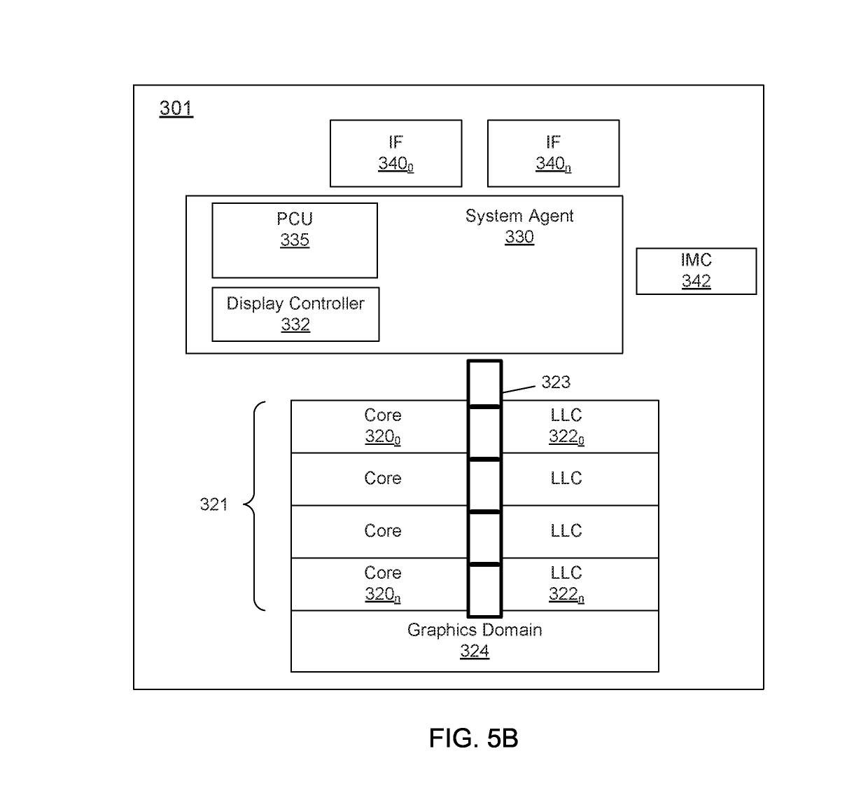

Referring to FIG. 4, an embodiment of a processor including multiple cores is illustrated. Processor 400 includes any processor or processing device, such as a microprocessor, an embedded processor, a digital signal processor (DSP), a network processor, a handheld processor, an application processor, a co-processor, a system on a chip (SoC), or other device to execute code. Processor 400, in one embodiment, includes at least two cores—cores 401 and 402, which may include asymmetric cores or symmetric cores (the illustrated embodiment). However, processor 400 may include any number of processing elements that may be symmetric or asymmetric. In some embodiments, various components of cores 401, 402 may implement the strand logic 125 shown in FIG. 1A.

In some embodiments, a processing element refers to hardware or logic to support a strand. A processing element, in some embodiments, may include any hardware capable of being independently associated with code, such as a strand, a thread, operating system, application, or other code. A physical processor typically refers to an integrated circuit, which potentially includes any number of other processing elements, such as cores.

A core often refers to logic located on an integrated circuit capable of maintaining an independent architectural state, wherein each independently maintained architectural state is associated with at least some dedicated execution resources. A processing way may refer to any logic included in a core that is capable of maintaining an independent architectural state for a strand, wherein independently maintained architectural states share access to execution resources. In some embodiments, a processing way can include a set of dedicated hardware components for executing a thread simultaneously with other threads in simultaneous multithreading (SMT) mode.

In the example shown in FIG. 4, the physical processor 400 includes two cores, namely cores 401 and 402. However, in other examples, the processor 400 may include any number of cores. Here, cores 401 and 402 are considered symmetric cores, i.e., cores with the same configurations, functional units, and/or logic. In some embodiment, cores 401 and 402 are out-of-order processor cores. In some embodiments, software entities, such as an operating system, potentially view processor 400 as four separate processing ways, i.e., four logical processors or processing elements capable of executing four strands concurrently. A first strand may be associated with architecture state registers 401a, a second strand may be associated with architecture state registers 401b, a third strand may be associated with architecture state registers 402a, and a fourth strand may be associated with architecture state registers 402b. Here, each of the architecture state registers (401a, 401b, 402a, and 402b) may be associated with a different processing way. As illustrated, architecture state registers 401a are replicated in architecture state registers 401b, so individual architecture states/contexts are capable of being stored for logical processor 401a and logical processor 401b. In core 401, other smaller resources, such as instruction pointers and renaming logic in allocator and renamer block 430 may also be replicated for different strands. In some embodiment, the architecture state registers (401a and 401b) of core 401 may be linked to provide communication between strands. Further, the architecture state registers (402a and 402b) of core 402 may be linked to provide communication between strands. For example, such communication may use cross-strand register data dependency indications in the compiled strand code.

In some embodiments, various resources such as re-order buffers in reorder/retirement unit 435, ILTB 420, load/store buffers, and queues may be divided into multiple partitions, with each partition being allocated to a particular strand and/or instruction group associated with a criticality level.

Core 401 further includes decode module 425 coupled to fetch unit 420 to decode fetched elements. Core 401 may be associated with an instruction set architecture (ISA), which defines/specifies instructions executable on processor 400. Often machine code instructions that are part of the ISA include a portion of the instruction (referred to as an opcode), which references/specifies an instruction or operation to be performed. Decode logic 425 includes circuitry that recognizes these instructions from their opcodes and passes the decoded instructions on in the pipeline for processing as defined by the ISA. For example, decoders 425, in one embodiment, include logic designed or adapted to recognize specific instructions, such as transactional instruction. As a result of the recognition by decoders 425, the architecture or core 401 takes specific, predefined actions to perform tasks associated with the appropriate instruction. It is important to note that any of the tasks, blocks, operations, and methods described herein may be performed in response to a single or multiple instructions; some of which may be new or old instructions.

In one example, allocator and renamer block 430 includes an allocator to reserve resources, such as register files to store instruction processing results. In some embodiments, the allocator and renamer block 430 may allocate strands in strand order (i.e., out of program order), and may reserve other resources, such as reorder buffers to track instruction results. Unit 430 may also include a register renamer to rename program/instruction reference registers to other registers internal to processor 400. Reorder/retirement unit 435 includes components, such as the reorder buffers mentioned above, load buffers, and store buffers, to support execution in strand order, and to support retirement in program order. Such buffers may be divided into multiple partitions, with each partition being allocated to a particular strand and/or instruction group associated with a criticality level.

Scheduler and execution unit(s) block 440, in one embodiment, includes a scheduler unit to schedule instructions/operations. For example, a floating point instruction is scheduled on a port of an execution unit that has an available floating point execution unit. Register files associated with the execution units are also included to store information instruction processing results. Exemplary execution units include a floating point execution unit, an integer execution unit, a jump execution unit, a load execution unit, a store execution unit, and other known execution units.

Lower level data cache and data translation buffer (D-TLB) 450 are coupled to execution unit(s) 440. The data cache is to store recently used/operated on elements, such as data operands, which are potentially held in memory coherency states. The D-TLB is to store recent virtual/linear to physical address translations. As a specific example, a processor may include a page table structure to break physical memory into a plurality of virtual pages.

Here, cores 401 and 402 share access to higher-level or further-out cache 410, which is to cache recently fetched elements. Note that higher-level or further-out refers to cache levels increasing or getting further away from the execution unit(s). In one embodiment, higher-level cache 410 is a last-level data cache—last cache in the memory hierarchy on processor 400—such as a second or third level data cache. However, higher level cache 410 is not so limited, as it may be associated with or includes an instruction cache. A trace cache—a type of instruction cache—instead may be coupled after decoder 425 to store recently decoded traces.

In the depicted configuration, processor 400 also includes bus interface module 405 and a power controller 460, which may perform power management in accordance with an embodiment of the present invention. In this scenario, bus interface 405 is to communicate with devices external to processor 400, such as system memory and other components.

A memory controller 470 may interface with other devices such as one or many memories. In an example, bus interface 405 includes a ring interconnect with a memory controller for interfacing with a memory and a graphics controller for interfacing with a graphics processor. In an SoC environment, even more devices, such as a network interface, coprocessors, memory, graphics processor, and any other known computer devices/interface may be integrated on a single die or integrated circuit to provide small form factor with high functionality and low power consumption.

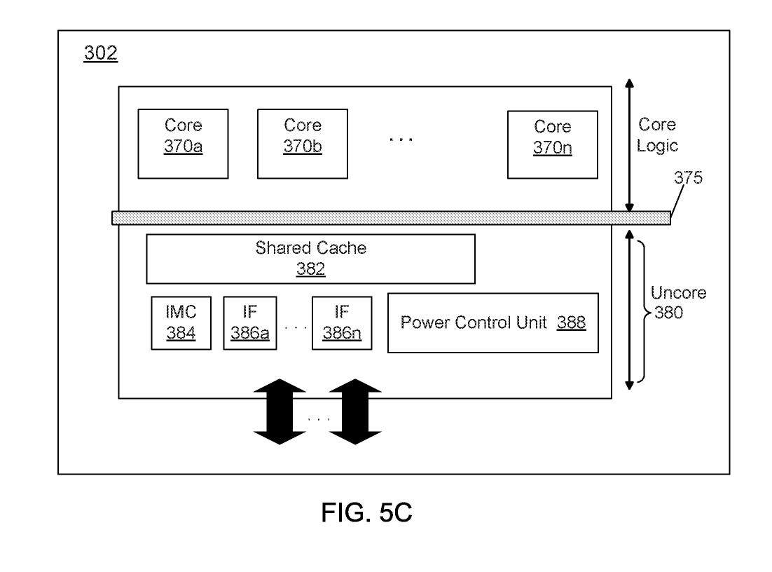

Referring now to FIG. 5A, shown is a block diagram of a system 300 in accordance with an embodiment of the present invention. As shown in FIG. 5A, system 300 may include various components, including a processor 303 which as shown is a multicore processor. Processor 303 may be coupled to a power supply 317 via an external voltage regulator 316, which may perform a first voltage conversion to provide a primary regulated voltage to processor 303.

As seen, processor 303 may be a single die processor including multiple cores 304ₐ-304ₙ. In addition, each core 304 may be associated with an integrated voltage regulator (IVR) 308ₐ-308ₙ which receives the primary regulated voltage and generates an operating voltage to be provided to one or more agents of the processor associated with the IVR 308. Accordingly, an IVR implementation may be provided to allow for fine-grained control of voltage and thus power and performance of each individual core 304. As such, each core 304 can operate at an independent voltage and frequency, enabling great flexibility and affording wide opportunities for balancing power consumption with performance. In some embodiments, the use of multiple IVRs 308 enables the grouping of components into separate power planes, such that power is regulated and supplied by the IVR 308 to only those components in the group. During power management, a given power plane of one IVR 308 may be powered down or off when the processor is placed into a certain low power state, while another power plane of another IVR 308 remains active, or fully powered.

Still referring to FIG. 5A, additional components may be present within the processor including an input/output interface 313, another interface 314, and an integrated memory controller 315. As seen, each of these components may be powered by another integrated voltage regulator 308ₓ. In one embodiment, interface 313 may be in accordance with the Intel® Quick Path Interconnect (QPI) protocol, which provides for point-to-point (PtP) links in a cache coherent protocol that includes multiple layers including a physical layer, a link layer and a protocol layer. In turn, interface 314 may be in accordance with a Peripheral Component Interconnect Express (PCIe™) specification, e.g., the PCI Express™ Specification Base Specification version 2.0 (published Jan. 17, 2007).

Also shown is a power control unit (PCU) 312, which may include hardware, software and/or firmware to perform power management operations with regard to processor 303. As seen, PCU 312 provides control information to external voltage regulator 316 via a digital interface to cause the external voltage regulator 316 to generate the appropriate regulated voltage. PCU 312 also provides control information to IVRs 308 via another digital interface to control the operating voltage generated (or to cause a corresponding IVR 308 to be disabled in a low power mode). In some embodiments, the control information provided to IVRs 308 may include a power state of a corresponding core 304.

In various embodiments, PCU 312 may include a variety of power management logic units to perform hardware-based power management. Such power management may be wholly processor controlled (e.g., by various processor hardware, and which may be triggered by workload and/or power, thermal or other processor constraints) and/or the power management may be performed responsive to external sources (such as a platform or management power management source or system software).

In some embodiments, the processor 303 and/or any of the cores 304 may implement some or all of the strand logic 125 shown in FIG. 1A. Further, understand that additional components may be present within processor 303 such as uncore logic, and other components such as internal memories, e.g., one or more levels of a cache memory hierarchy and so forth.

Embodiments can be implemented in processors for various markets including server processors, desktop processors, mobile processors and so forth. Referring now to FIG. 5B, shown is a block diagram of a multi-domain processor 301 in accordance with one or more embodiments. As shown in the embodiment of FIG. 5B, processor 301 includes multiple domains. Specifically, a core domain 321 can include a plurality of cores 320₀-320ₙ, a graphics domain 324 can include one or more graphics engines, and a system agent domain 330 may further be present. In some embodiments, system agent domain 330 may execute at an independent frequency than the core domain and may remain powered on at all times to handle power control events and power management such that domains 321 and 324 can be controlled to dynamically enter into and exit high power and low power states. Each of domains 321 and 324 may operate at different voltage and/or power. Note that while only shown with three domains, understand the scope of the present invention is not limited in this regard and additional domains can be present in other embodiments. For example, multiple core domains may be present, with each core domain including at least one core.

In general, each core 320 may further include low level caches in addition to various execution units and additional processing elements. In turn, the various cores may be coupled to each other and to a shared cache memory formed of a plurality of units of a last level cache (LLC) 322₀-322ₙ. In various embodiments, LLC 322 may be shared amongst the cores and the graphics engine, as well as various media processing circuitry. As seen, a ring interconnect 323 thus couples the cores together, and provides interconnection between the cores 320, graphics domain 324 and system agent domain 330. In one embodiment, interconnect 323 can be part of the core domain 321. However, in other embodiments, the ring interconnect 323 can be of its own domain.

As further seen, system agent domain 330 may include display controller 332 which may provide control of and an interface to an associated display. In addition, system agent domain 330 may include a power control unit 335 to perform power management.

As further seen in FIG. 5B, processor 301 can further include an integrated memory controller (IMC) 342 that can provide for an interface to a system memory, such as a dynamic random access memory (DRAM). Multiple interfaces 340₀-340ₙ may be present to enable interconnection between the processor and other circuitry. For example, in one embodiment at least one direct media interface (DMI) interface may be provided as well as one or more PCIe™ interfaces. Still further, to provide for communications between other agents such as additional processors or other circuitry, one or more interfaces in accordance with an Intel® Quick Path Interconnect (QPI) protocol may also be provided. Although shown at this high level in the embodiment of FIG. 3B, understand the scope of the present invention is not limited in this regard.

In some embodiments, processor 301 and/or the cores 320₀-320ₙ may implement the strand logic 125 shown in FIG. 1A. Further, understand that additional components may be present within processor 301.

Referring now to FIG. 5C, shown is a block diagram of a processor 302 in accordance with an embodiment of the present invention. As shown in FIG. 5C, processor 302 may be a multicore processor including a plurality of cores 370ₐ-370ₙ. In one embodiment, each such core may be of an independent power domain and can be configured to enter and exit active states and/or maximum performance states based on workload. The various cores may be coupled via an interconnect 375 to a system agent or uncore 380 that includes various components. As seen, the uncore 380 may include a shared cache 382 which may be a last level cache. In addition, the uncore 380 may include an integrated memory controller 384 to communicate with a system memory (not shown in FIG. 5C), e.g., via a memory bus. Uncore 380 also includes various interfaces 386a-386n and a power control unit 388, which may include logic to perform the power management techniques described herein.

In addition, by interfaces 386a-386n, connection can be made to various off-chip components such as peripheral devices, mass storage and so forth. In some embodiments, processor 302 and/or any of the cores 370a-370n may implement the strand logic 125 shown in FIG. 1A.

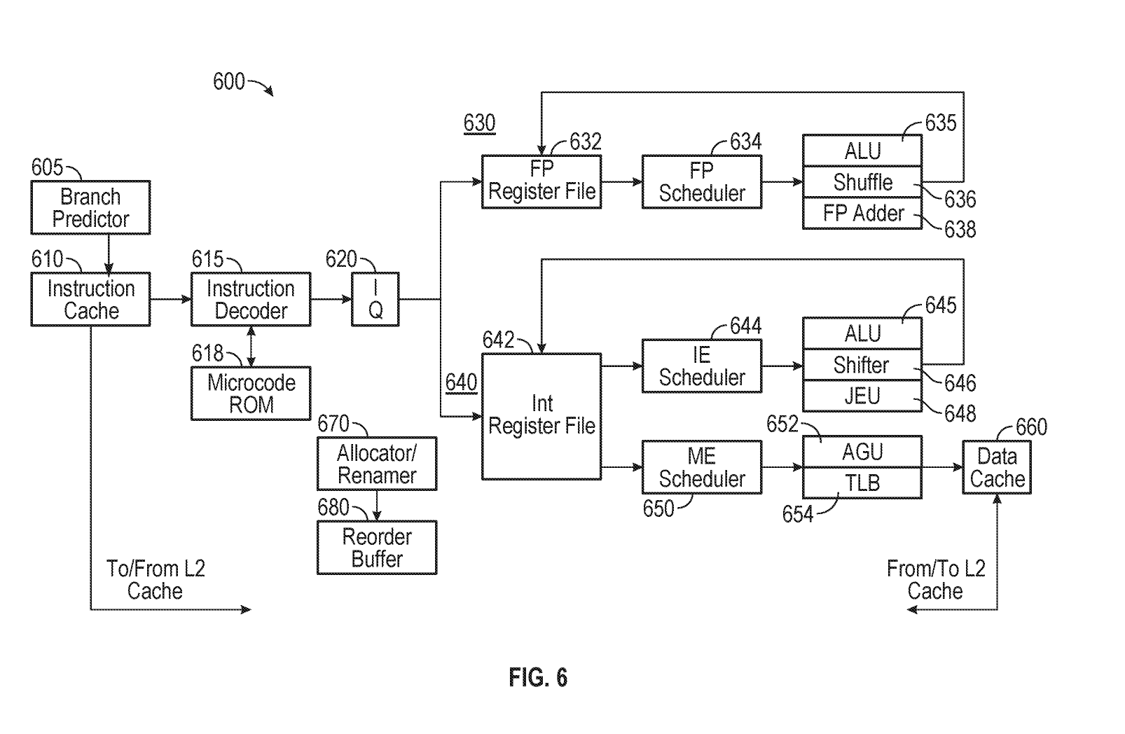

Referring now to FIG. 6, shown is a block diagram of a micro-architecture of a processor core in accordance with another embodiment. In the embodiment of FIG. 6, core 600 may be a low power core of a different micro-architecture, such as an Intel® Atom™-based processor having a relatively limited pipeline depth designed to reduce power consumption. In some embodiments, the core 600 may implement the strand logic 125 shown in FIG. 1A.

As shown, core 600 includes an instruction cache 610 coupled to provide instructions to an instruction decoder 615. A branch predictor 605 may be coupled to instruction cache 610. Note that instruction cache 610 may further be coupled to another level of a cache memory, such as an L2 cache (not shown for ease of illustration in FIG. 6). In turn, instruction decoder 615 provides decoded instructions to an issue queue 620 for storage and delivery to a given execution pipeline. A microcode ROM 618 is coupled to instruction decoder 615.

A floating point pipeline 630 includes a floating point register file 632 which may include a plurality of architectural registers of a given bit with such as 128, 256 or 512 bits. Pipeline 630 includes a floating point scheduler 634 to schedule instructions for execution on one of multiple execution units of the pipeline. In the embodiment shown, such execution units include an ALU 635, a shuffle unit 636, and a floating point adder 638. In turn, results generated in these execution units may be provided back to buffers and/or registers of register file 632. Of course understand while shown with these few example execution units, additional or different floating point execution units may be present in another embodiment.

An integer pipeline 640 also may be provided. In the embodiment shown, pipeline 640 includes an integer register file 642 which may include a plurality of architectural registers of a given bit with such as 128 or 256 bits. Pipeline 640 includes an integer scheduler 644 to schedule instructions for execution on one of multiple execution units of the pipeline. In the embodiment shown, such execution units include an ALU 645, a shifter unit 646, and a jump execution unit 648. In turn, results generated in these execution units may be provided back to buffers and/or registers of register file 642. Of course understand while shown with these few example execution units, additional or different integer execution units may be present in another embodiment.

A memory execution scheduler 650 may schedule memory operations for execution in an address generation unit 652, which is also coupled to a TLB 654. As seen, these structures may couple to a data cache 660, which may be a L0 and/or L1 data cache that in turn couples to additional levels of a cache memory hierarchy, including an L2 cache memory.

To provide support for out-of-order execution, an allocator/renamer 670 may be provided, in addition to a reorder buffer 680, which is configured to reorder instructions executed out of order for retirement in order. Although shown with this particular pipeline architecture in the illustration of FIG. 6, understand that many variations and alternatives are possible.

Note that in a processor having asymmetric cores, such as in accordance with the micro-architectures of FIGS. 5 and 6, workloads may be dynamically swapped between the cores for power management reasons, as these cores, although having different pipeline designs and depths, may be of the same or related ISA. Such dynamic core swapping may be performed in a manner transparent to a user application (and possibly kernel also).

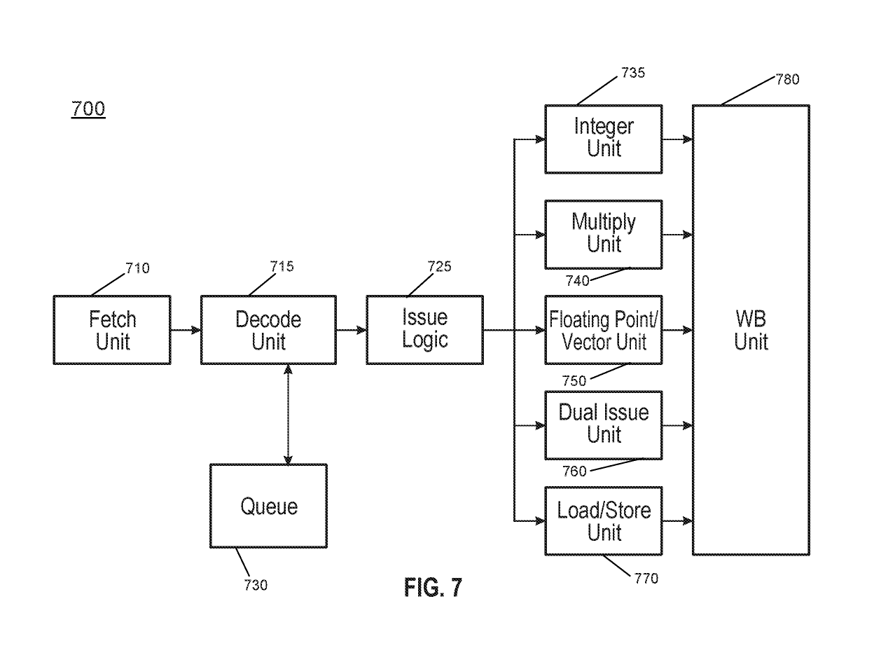

Referring to FIG. 7, shown is a block diagram of a micro-architecture of a processor core in accordance with yet another embodiment. As illustrated in FIG. 7, a core 700 may include a multi-staged in-order pipeline to execute at very low power consumption levels. In some embodiments, the core 700 may implement the strand logic 125 shown in FIG. 1A.

In an implementation, core 700 may include an 8-stage pipeline that is configured to execute both 32-bit and 64-bit code. Core 700 includes a fetch unit 710 that is configured to fetch instructions and provide them to a decode unit 715, which may decode the instructions, e.g., macro-instructions of a given ISA such as an ARMv8 ISA. Note further that a queue 730 may couple to decode unit 715 to store decoded instructions. Decoded instructions are provided to an issue logic 725, where the decoded instructions may be issued to a given one of multiple execution units.

With further reference to FIG. 7, issue logic 725 may issue instructions to one of multiple execution units. In the embodiment shown, these execution units include an integer unit 735, a multiply unit 740, a floating point/vector unit 750, a dual issue unit 760, and a load/store unit 770. The results of these different execution units may be provided to a writeback unit 780. Understand that while a single writeback unit is shown for ease of illustration, in some implementations separate writeback units may be associated with each of the execution units. Furthermore, understand that while each of the units and logic shown in FIG. 7 is represented at a high level, a particular implementation may include more or different structures. A processor designed using one or more cores having a pipeline as in FIG. 7 may be implemented in many different end products, extending from mobile devices to server systems.

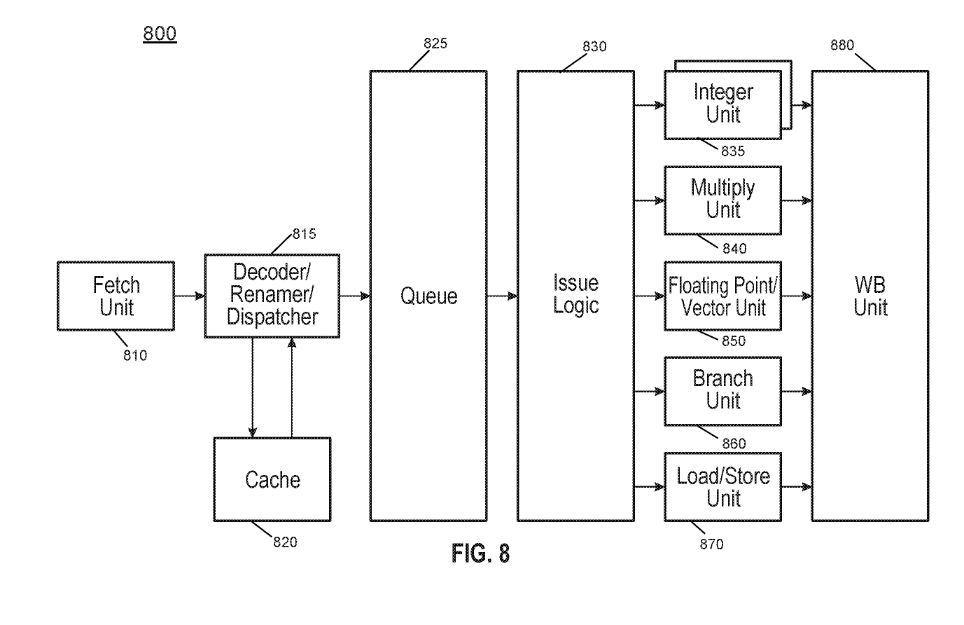

Referring now to FIG. 8, shown is a block diagram of a micro-architecture of a processor core in accordance with a still further embodiment. As illustrated in FIG. 8, a core 800 may include a multi-stage multi-issue out-of-order pipeline to execute at very high performance levels (which may occur at higher power consumption levels than core 700 of FIG. 7). In some embodiments, the core 800 may implement the strand logic 125 shown in FIG. 1A.

In an implementation, the core 800 may provide a 15 (or greater)-stage pipeline that is configured to execute both 32-bit and 64-bit code. In addition, the pipeline may provide for 3 (or greater)-wide and 3 (or greater)-issue operation. Core 800 includes a fetch unit 810 that is configured to fetch instructions and provide them to a decoder/renamer/dispatcher 815, which may decode the instructions, e.g., macro-instructions of an ARMv8 instruction set architecture, rename register references within the instructions, and dispatch the instructions (eventually) to a selected execution unit. Decoded instructions may be stored in a queue 825. Note that while a single queue structure is shown for ease of illustration in FIG. 8, understand that separate queues may be provided for each of the multiple different types of execution units.

Also shown in FIG. 8 is an issue logic 830 from which decoded instructions stored in queue 825 may be issued to a selected execution unit. Issue logic 830 also may be implemented in a particular embodiment with a separate issue logic for each of the multiple different types of execution units to which issue logic 830 couples.

Decoded instructions may be issued to a given one of multiple execution units. In the embodiment shown, these execution units include one or more integer units 835, a multiply unit 840, a floating point/vector unit 850, a branch unit 860, and a load/store unit 870. In an embodiment, floating point/vector unit 850 may be configured to handle SIMD or vector data of 128 or 256 bits. Still further, floating point/vector execution unit 850 may perform IEEE-754 double precision floating-point operations. The results of these different execution units may be provided to a writeback unit 880. Note that in some implementations separate writeback units may be associated with each of the execution units. Furthermore, understand that while each of the units and logic shown in FIG. 8 is represented at a high level, a particular implementation may include more or different structures.

Note that in a processor having asymmetric cores, such as in accordance with the micro-architectures of FIGS. 7 and 8, workloads may be dynamically swapped for power management reasons, as these cores, although having different pipeline designs and depths, may be of the same or related ISA. Such dynamic core swapping may be performed in a manner transparent to a user application (and possibly kernel also).

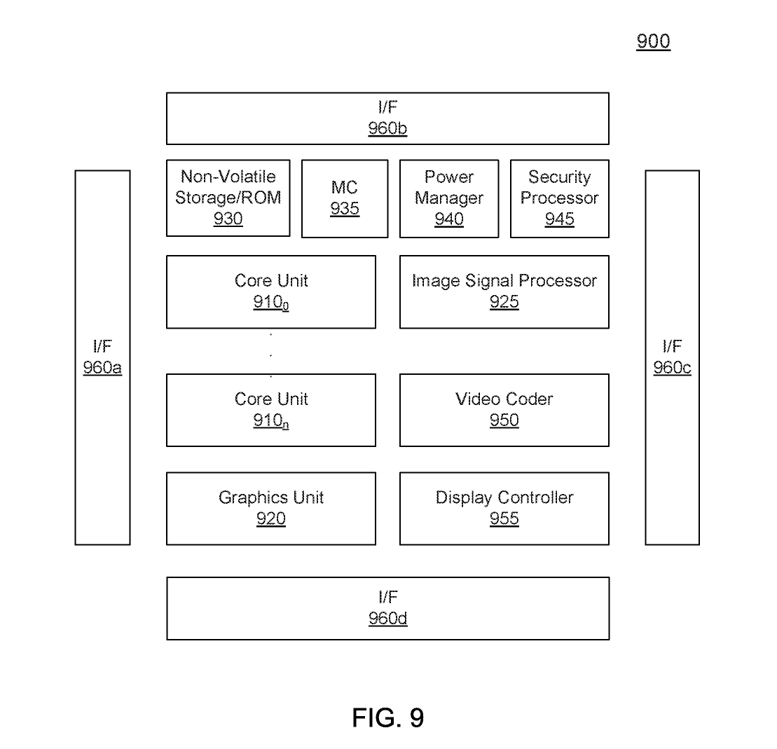

A processor designed using one or more cores having pipelines as in any one or more of FIGS. 5-8 may be implemented in many different end products, extending from mobile devices to server systems. Referring now to FIG. 9, shown is a block diagram of a processor in accordance with another embodiment of the present invention. In the embodiment of FIG. 9, a system on a chip (SoC) 900 may include multiple domains, each of which may be controlled to operate at an independent operating voltage and operating frequency. In some embodiments, the SoC 900 may implement the strand logic 125 shown in FIG. 1A.

In the high level view shown in FIG. 9, processor 900 includes a plurality of core units 910₀-910ₙ. Each core unit may include one or more processor cores, one or more cache memories and other circuitry. Each core unit 910 may support one or more instructions sets (e.g., an x86 instruction set (with some extensions that have been added with newer versions); a MIPS instruction set; an ARM instruction set (with optional additional extensions such as NEONe)) or other instruction set or combinations thereof. Note that some of the core units may be heterogeneous resources (e.g., of a different design). In addition, each such core may be coupled to a cache memory (not shown) which in an embodiment may be a shared level (L2) cache memory. A non-volatile storage 930 may be used to store various program and other data. For example, this storage may be used to store at least portions of microcode, boot information such as a BIOS, other system software or so forth.

Each core unit 910 may also include an interface such as a bus interface unit to enable interconnection to additional circuitry of the processor. In an embodiment, each core unit 910 couples to a coherent fabric that may act as a primary cache coherent on-die interconnect that in turn couples to a memory controller 935. In turn, memory controller 935 controls communications with a memory such as a DRAM (not shown for ease of illustration in FIG. 9).

In addition to core units, additional processor engines are present within the processor, including at least one graphics unit 920 which may include one or more graphics processing units (GPUs) to perform graphics processing as well as to possibly execute general purpose operations on the graphics processor (so-called GPGPU operation). In addition, at least one image signal processor 925 may be present. Signal processor 925 may be configured to process incoming image data received from one or more capture devices, either internal to the SoC or off-chip.

Other accelerators also may be present. In the illustration of FIG. 9, a video coder 950 may perform coding operations including encoding and decoding for video information, e.g., providing hardware acceleration support for high definition video content. A display controller 955 further may be provided to accelerate display operations including providing support for internal and external displays of a system. In addition, a security processor 945 may be present to perform security operations such as secure boot operations, various cryptography operations and so forth.

Each of the units may have its power consumption controlled via a power manager 940, which may include control logic to perform the various power management techniques described herein.

In some embodiments, SoC 900 may further include a non-coherent fabric coupled to the coherent fabric to which various peripheral devices may couple. One or more interfaces 960a-960d enable communication with one or more off-chip devices. Such communications may be according to a variety of communication protocols such as PCIe™, GPIO, USB, I²C, UART, MIPI, SDIO, DDR, SPI, HDMI, among other types of communication protocols. Although shown at this high level in the embodiment of FIG. 9, understand the scope of the present invention is not limited in this regard.

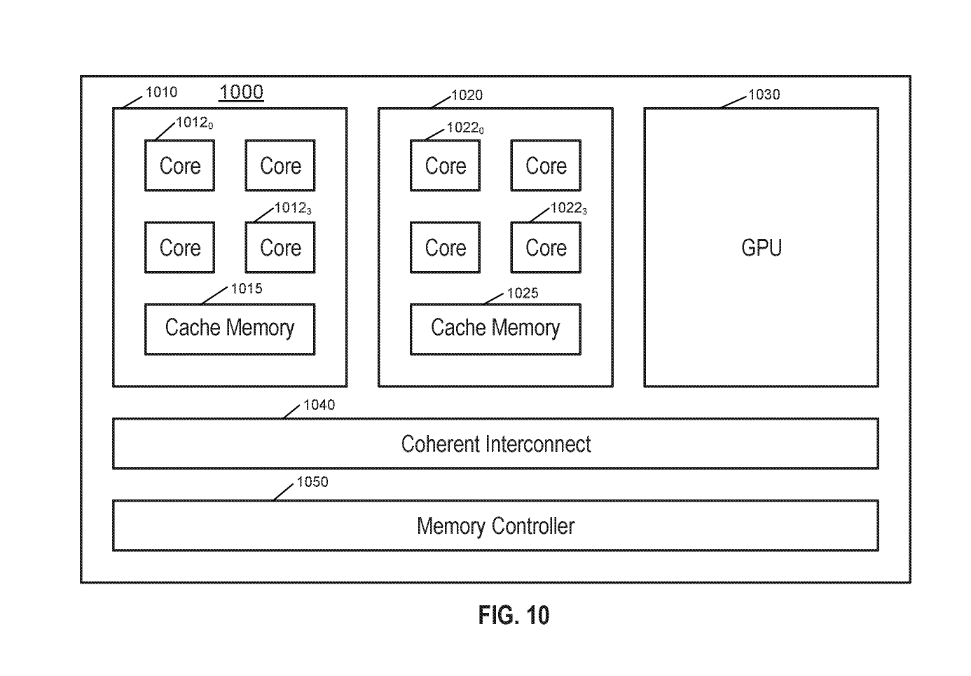

Referring now to FIG. 10, shown is a block diagram of a representative SoC. In the embodiment shown, SoC 1000 may be a multi-core SoC configured for low power operation to be optimized for incorporation into a smartphone or other low power device such as a tablet computer or other portable computing device. In some embodiments, the SoC 1000 may implement the strand logic 125 shown in FIG. 1A.

As seen in FIG. 10, SoC 1000 includes a first core domain 1010 having a plurality of first cores 1012₀-1012₃. In an example, these cores may be low power cores such as in-order cores. In one embodiment these first cores may be implemented as ARM Cortex A53 cores. In turn, these cores couple to a cache memory 1015 of core domain 1010. In addition, SoC 1000 includes a second core domain 1020. In the illustration of FIG. 10, second core domain 1020 has a plurality of second cores 1022₀-1022₃. In an example, these cores may be higher power-consuming cores than first cores 1012. In an embodiment, the second cores may be out-of-order cores, which may be implemented as ARM Cortex A57 cores. In turn, these cores couple to a cache memory 1025 of core domain 1020. Note that while the example shown in FIG. 10 includes 4 cores in each domain, understand that more or fewer cores may be present in a given domain in other examples.

With further reference to FIG. 10, a graphics domain 1030 also is provided, which may include one or more graphics processing units (GPUs) configured to independently execute graphics workloads, e.g., provided by one or more cores of core domains 1010 and 1020. As an example, GPU domain 1030 may be used to provide display support for a variety of screen sizes, in addition to providing graphics and display rendering operations.

As seen, the various domains couple to a coherent interconnect 1040, which in an embodiment may be a cache coherent interconnect fabric that in turn couples to an integrated memory controller 1050. Coherent interconnect 1040 may include a shared cache memory, such as an L3 cache, some examples. In an embodiment, memory controller 1050 may be a direct memory controller to provide for multiple channels of communication with an off-chip memory, such as multiple channels of a DRAM (not shown for ease of illustration in FIG. 10).

In different examples, the number of the core domains may vary. For example, for a low power SoC suitable for incorporation into a mobile computing device, a limited number of core domains such as shown in FIG. 10 may be present. Still further, in such low power SoCs, core domain 1020 including higher power cores may have fewer numbers of such cores. For example, in one implementation two cores 1022 may be provided to enable operation at reduced power consumption levels. In addition, the different core domains may also be coupled to an interrupt controller to enable dynamic swapping of workloads between the different domains.

In yet other embodiments, a greater number of core domains, as well as additional optional IP logic may be present, in that an SoC can be scaled to higher performance (and power) levels for incorporation into other computing devices, such as desktops, servers, high performance computing systems, base stations forth. As one such example, 4 core domains each having a given number of out-of-order cores may be provided. Still further, in addition to optional GPU support (which as an example may take the form of a GPGPU), one or more accelerators to provide optimized hardware support for particular functions (e.g. web serving, network processing, switching or so forth) also may be provided. In addition, an input/output interface may be present to couple such accelerators to off-chip components.

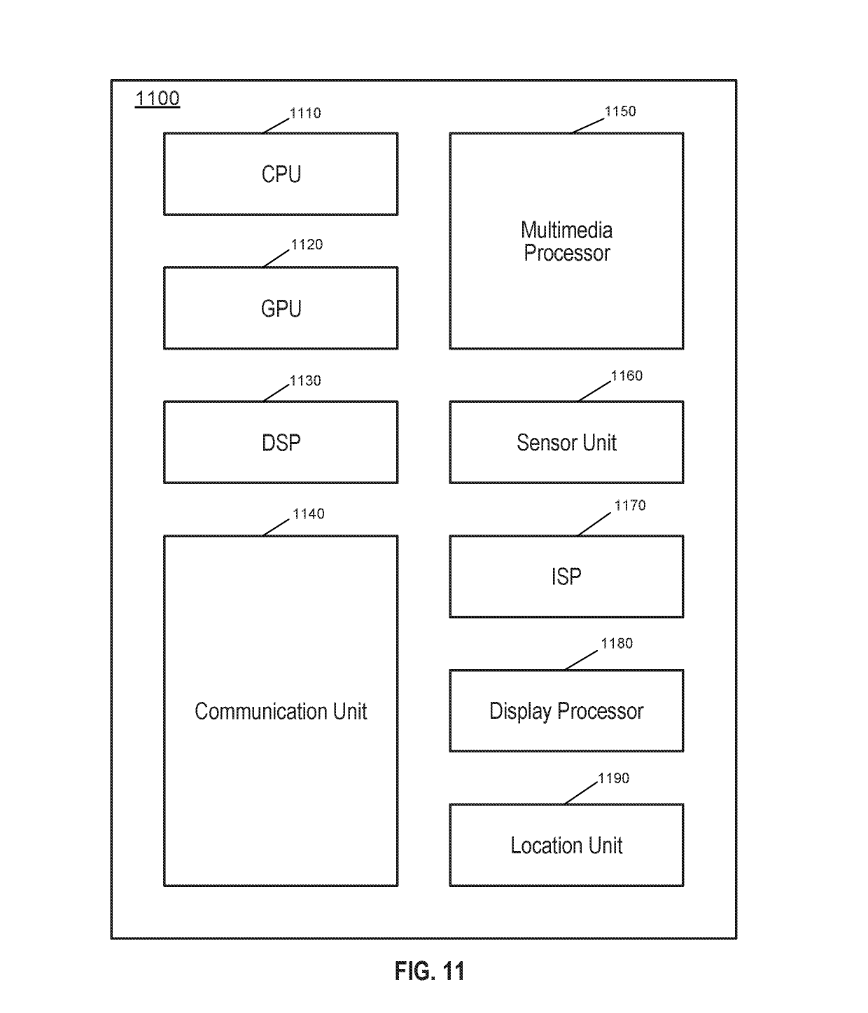

Referring now to FIG. 11, shown is a block diagram of another example SoC 1100. In some embodiments, the SoC 1100 may implement the strand logic 125 shown in FIG. 1A.

In the embodiment of FIG. 11, SoC 1100 may include various circuitry to enable high performance for multimedia applications, communications and other functions. As such, SoC 1100 is suitable for incorporation into a wide variety of portable and other devices, such as smartphones, tablet computers, smart TVs and so forth. In the example shown, SoC 1100 includes a central processor unit (CPU) domain 1110. In an embodiment, a plurality of individual processor cores may be present in CPU domain 1110. As one example, CPU domain 1110 may be a quad core processor having 4 multithreaded cores. Such processors may be homogeneous or heterogeneous processors, e.g., a mix of low power and high power processor cores.

In turn, a GPU domain 1120 is provided to perform advanced graphics processing in one or more GPUs to handle graphics and compute APIs. A DSP unit 1130 may provide one or more low power DSPs for handling low-power multimedia applications such as music playback, audio/video and so forth, in addition to advanced calculations that may occur during execution of multimedia instructions. In turn, a communication unit 1140 may include various components to provide connectivity via various wireless protocols, such as cellular communications (including 3G/4G LTE), wireless local area techniques such as Bluetooth™, IEEE 802.11, and so forth.

Still further, a multimedia processor 1150 may be used to perform capture and playback of high definition video and audio content, including processing of user gestures. A sensor unit 1160 may include a plurality of sensors and/or a sensor controller to interface to various off-chip sensors present in a given platform. An image signal processor 1170 may be provided with one or more separate ISPs to perform image processing with regard to captured content from one or more cameras of a platform, including still and video cameras.

A display processor 1180 may provide support for connection to a high definition display of a given pixel density, including the ability to wirelessly communicate content for playback on such display. Still further, a location unit 1190 may include a GPS receiver with support for multiple GPS constellations to provide applications highly accurate positioning information obtained using as such GPS receiver. Understand that while shown with this particular set of components in the example of FIG. 11, many variations and alternatives are possible.

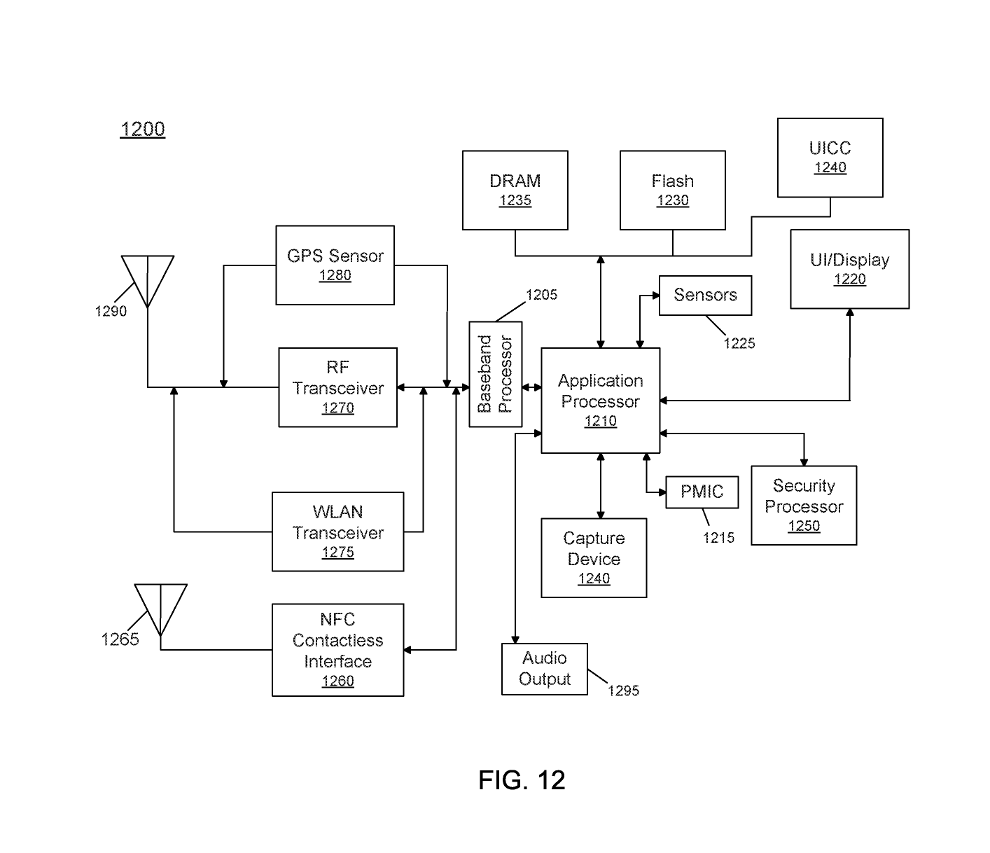

Referring now to FIG. 12, shown is a block diagram of an example system 1200 with which embodiments can be used. In some embodiments, components of the system 1200 may implement the strand logic 125 shown in FIG. 1A.

As seen, system 1200 may be a smartphone or other wireless communicator. A baseband processor 1205 is configured to perform various signal processing with regard to communication signals to be transmitted from or received by the system. In turn, baseband processor 1205 is coupled to an application processor 1210, which may be a main CPU of the system to execute an OS and other system software, in addition to user applications such as many well-known social media and multimedia apps. Application processor 1210 may further be configured to perform a variety of other computing operations for the device.

In turn, application processor 1210 can couple to a user interface/display 1220, e.g., a touch screen display. In addition, application processor 1210 may couple to a memory system including a non-volatile memory, namely a flash memory 1230 and a system memory, namely a dynamic random access memory (DRAM) 1235. As further seen, application processor 1210 further couples to a capture device 1240 such as one or more image capture devices that can record video and/or still images.

Still referring to FIG. 12, a universal integrated circuit card (UICC) 1240 comprising a subscriber identity module and possibly a secure storage and cryptoprocessor is also coupled to application processor 1210. System 1200 may further include a security processor 1250 that may couple to application processor 1210. A plurality of sensors 1225 may couple to application processor 1210 to enable input of a variety of sensed information such as accelerometer and other environmental information. An audio output device 1295 may provide an interface to output sound, e.g., in the form of voice communications, played or streaming audio data and so forth.

As further illustrated, a near field communication (NFC) contactless interface 1260 is provided that communicates in a NFC near field via an NFC antenna 1265. While separate antennae are shown in FIG. 12, understand that in some implementations one antenna or a different set of antennae may be provided to enable various wireless functionality.

A power management integrated circuit (PMIC) 1215 couples to application processor 1210 to perform platform level power management. To this end, PMIC 1215 may issue power management requests to application processor 1210 to enter certain low power states as desired. Furthermore, based on platform constraints, PMIC 1215 may also control the power level of other components of system 1200.

To enable communications to be transmitted and received, various circuitry may be coupled between baseband processor 1205 and an antenna 1290. Specifically, a radio frequency (RF) transceiver 1270 and a wireless local area network (WLAN) transceiver 1275 may be present. In general, RF transceiver 1270 may be used to receive and transmit wireless data and calls according to a given wireless communication protocol such as 3G or 4G wireless communication protocol such as in accordance with a code division multiple access (CDMA), global system for mobile communication (GSM), long term evolution (LTE) or other protocol. In addition a GPS sensor 1280 may be present. Other wireless communications such as receipt or transmission of radio signals, e.g., AM/FM and other signals may also be provided. In addition, via WLAN transceiver 1275, local wireless communications, such as according to a Bluetooth™ standard or an IEEE 802.11 standard such as IEEE 802.11a/b/g/n can also be realized.

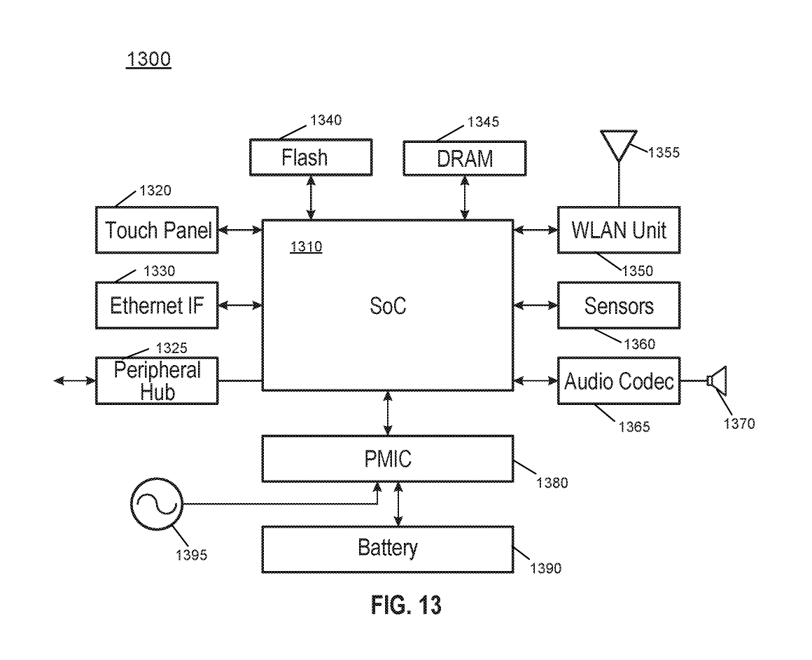

Referring now to FIG. 13, shown is a block diagram of another example system 1300 with which embodiments may be used. In the illustration of FIG. 13, system 1300 may be mobile low-power system such as a tablet computer, 2:1 tablet, phablet or other convertible or standalone tablet system. As illustrated, a SoC 1310 is present and may be configured to operate as an application processor for the device. In some embodiments, the SoC 1310 may implement the strand logic 125 shown in FIG. 1A.

A variety of devices may couple to SoC 1310. In the illustration shown, a memory subsystem includes a flash memory 1340 and a DRAM 1345 coupled to SoC 1310. In addition, a touch panel 1320 is coupled to the SoC 1310 to provide display capability and user input via touch, including provision of a virtual keyboard on a display of touch panel 1320. To provide wired network connectivity, SoC 1310 couples to an Ethernet interface 1330. A peripheral hub 1325 is coupled to SoC 1310 to enable interfacing with various peripheral devices, such as may be coupled to system 1300 by any of various ports or other connectors.

In addition to internal power management circuitry and functionality within SoC 1310, a PMIC 1380 is coupled to SoC 1310 to provide platform-based power management, e.g., based on whether the system is powered by a battery 1390 or AC power via an AC adapter 1395. In addition to this power source-based power management, PMIC 1380 may further perform platform power management activities based on environmental and usage conditions. Still further, PMIC 1380 may communicate control and status information to SoC 1310 to cause various power management actions within SoC 1310.

Still referring to FIG. 13, to provide for wireless capabilities, a WLAN unit 1350 is coupled to SoC 1310 and in turn to an antenna 1355. In various implementations, WLAN unit 1350 may provide for communication according to one or more wireless protocols, including an IEEE 802.11 protocol, a Bluetooth™ protocol or any other wireless protocol.

As further illustrated, a plurality of sensors 1360 may couple to SoC 1310. These sensors may include various accelerometer, environmental and other sensors, including user gesture sensors. Finally, an audio codec 1365 is coupled to SoC 1310 to provide an interface to an audio output device 1370. Of course understand that while shown with this particular implementation in FIG. 13, many variations and alternatives are possible.

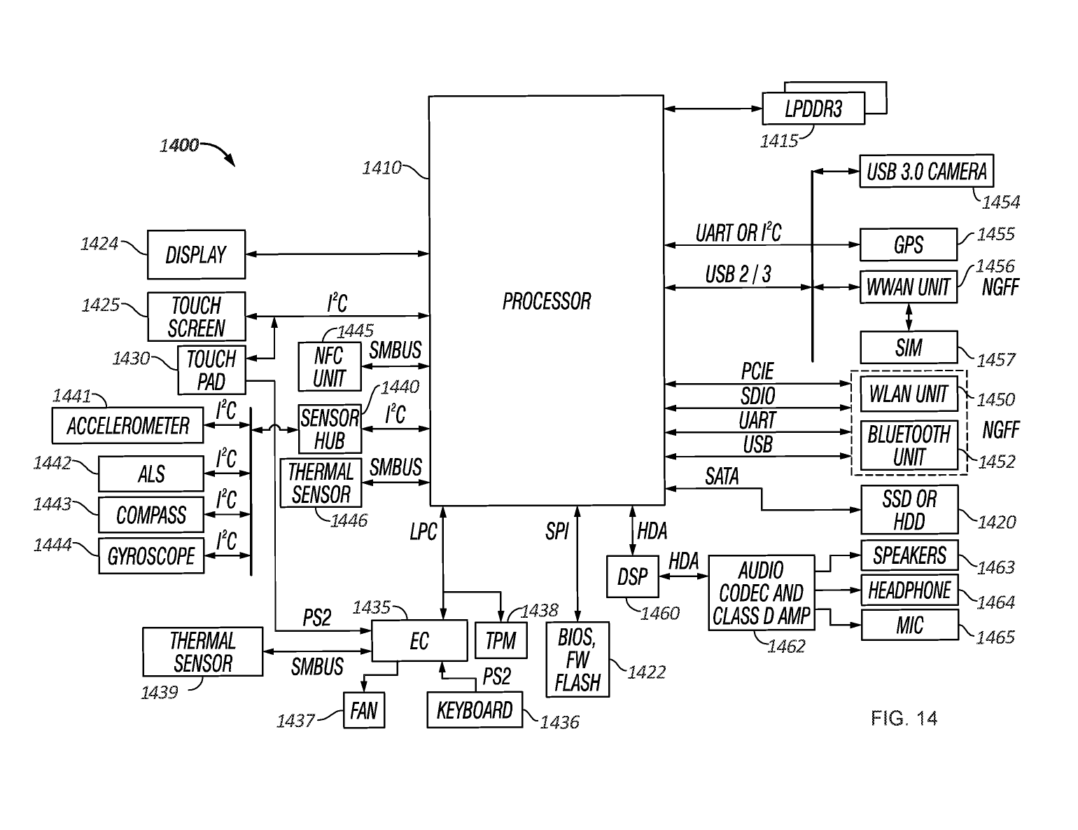

Referring now to FIG. 14, a block diagram of a representative computer system 1400 such as notebook, Ultrabook™ or other small form factor system. A processor 1410, in one embodiment, includes a microprocessor, multi-core processor, multithreaded processor, an ultra low voltage processor, an embedded processor, or other known processing element. In the illustrated implementation, processor 1410 acts as a main processing unit and central hub for communication with many of the various components of the system 1400. As one example, processor 1410 is implemented as a SoC. In some embodiments, processor 1410 may implement the strand logic 125 shown in FIG. 1A.

Processor 1410, in one embodiment, communicates with a system memory 1415. As an illustrative example, the system memory 1415 is implemented via multiple memory devices or modules to provide for a given amount of system memory.

To provide for persistent storage of information such as data, applications, one or more operating systems and so forth, a mass storage 1420 may also couple to processor 1410. In various embodiments, to enable a thinner and lighter system design as well as to improve system responsiveness, this mass storage may be implemented via a SSD or the mass storage may primarily be implemented using a hard disk drive (HDD) with a smaller amount of SSD storage to act as a SSD cache to enable non-volatile storage of context state and other such information during power down events so that a fast power up can occur on re-initiation of system activities. Also shown in FIG. 14, a flash device 1422 may be coupled to processor 1410, e.g., via a serial peripheral interface (SPI). This flash device may provide for non-volatile storage of system software, including a basic input/output software (BIOS) as well as other firmware of the system.

Various input/output (I/O) devices may be present within system 1400. Specifically shown in the embodiment of FIG. 14 is a display 1424 which may be a high definition LCD or LED panel that further provides for a touch screen 1425. In one embodiment, display 1424 may be coupled to processor 1410 via a display interconnect that can be implemented as a high performance graphics interconnect. Touch screen 1425 may be coupled to processor 1410 via another interconnect, which in an embodiment can be an I²C interconnect. As further shown in FIG. 14, in addition to touch screen 1425, user input by way of touch can also occur via a touch pad 1430 which may be configured within the chassis and may also be coupled to the same I²C interconnect as touch screen 1425.

For perceptual computing and other purposes, various sensors may be present within the system and may be coupled to processor 1410 in different manners. Certain inertial and environmental sensors may couple to processor 1410 through a sensor hub 1440, e.g., via an I²C interconnect. In the embodiment shown in FIG. 14, these sensors may include an accelerometer 1441, an ambient light sensor (ALS) 1442, a compass 1443 and a gyroscope 1444. Other environmental sensors may include one or more thermal sensors 1446 which in some embodiments couple to processor 1410 via a system management bus (SMBus) bus.

Also seen in FIG. 14, various peripheral devices may couple to processor 1410 via a low pin count (LPC) interconnect. In the embodiment shown, various components can be coupled through an embedded controller 1435. Such components can include a keyboard 1436 (e.g., coupled via a PS2 interface), a fan 1437, and a thermal sensor 1439. In some embodiments, touch pad 1430 may also couple to EC 1435 via a PS2 interface. In addition, a security processor such as a trusted platform module (TPM) 1438 in accordance with the Trusted Computing Group (TCG) TPM Specification Version 1.2, dated Oct. 2, 2003, may also couple to processor 1410 via this LPC interconnect.

System 1400 can communicate with external devices in a variety of manners, including wirelessly. In the embodiment shown in FIG. 14, various wireless modules, each of which can correspond to a radio configured for a particular wireless communication protocol, are present. One manner for wireless communication in a short range such as a near field may be via a NFC unit 1445 which may communicate, in one embodiment with processor 1410 via an SMBus. Note that via this NFC unit 1445, devices in close proximity to each other can communicate.

As further seen in FIG. 14, additional wireless units can include other short range wireless engines including a WLAN unit 1450 and a Bluetooth unit 1452. Using WLAN unit 1450, Wi-Fi™ communications in accordance with a given IEEE 802.11 standard can be realized, while via Bluetooth unit 1452, short range communications via a Bluetooth protocol can occur. These units may communicate with processor 1410 via, e.g., a USB link or a universal asynchronous receiver transmitter (UART) link. Or these units may couple to processor 1410 via an interconnect according to a PCIe™ protocol or another such protocol such as a serial data input/output (SDIO) standard.

In addition, wireless wide area communications, e.g., according to a cellular or other wireless wide area protocol, can occur via a WWAN unit 1456 which in turn may couple to a subscriber identity module (SIM) 1457. In addition, to enable receipt and use of location information, a GPS module 1455 may also be present. Note that in the embodiment shown in FIG. 14, WWAN unit 1456 and an integrated capture device such as a camera module 1454 may communicate via a given USB protocol such as a USB 2.0 or 3.0 link, or a UART or I²C protocol.

An integrated camera module 1454 can be incorporated in the lid. To provide for audio inputs and outputs, an audio processor can be implemented via a digital signal processor (DSP) 1460, which may couple to processor 1410 via a high definition audio (HDA) link. Similarly, DSP 1460 may communicate with an integrated coder/decoder (CODEC) and amplifier 1462 that in turn may couple to output speakers 1463 which may be implemented within the chassis. Similarly, amplifier and CODEC 1462 can be coupled to receive audio inputs from a microphone 1465 which in an embodiment can be implemented via dual array microphones (such as a digital microphone array) to provide for high quality audio inputs to enable voice-activated control of various operations within the system. Note also that audio outputs can be provided from amplifier/CODEC 1462 to a headphone jack 1464. Although shown with these particular components in the embodiment of FIG. 14, understand the scope of the present invention is not limited in this regard.

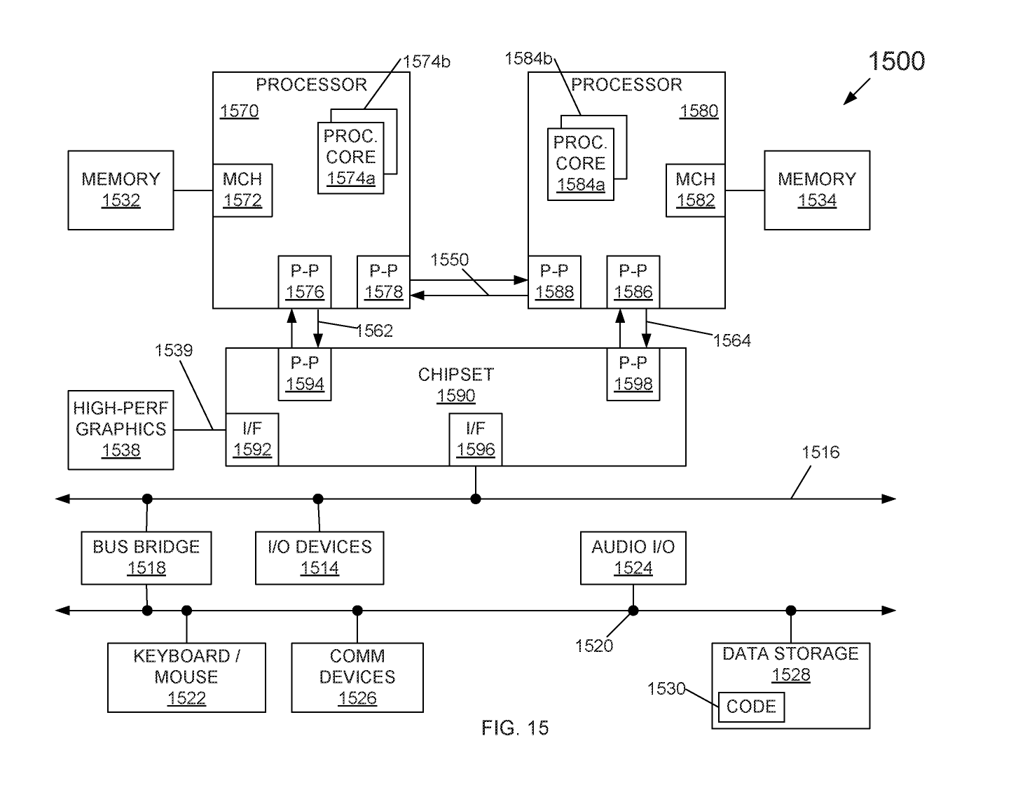

Embodiments may be implemented in many different system types. Referring now to FIG. 15, shown is a block diagram of a system in accordance with an embodiment of the present invention. As shown in FIG. 15, multiprocessor system 1500 is a point-to-point interconnect system, and includes a first processor 1570 and a second processor 1580 coupled via a point-to-point interconnect 1550. As shown in FIG. 15, each of processors 1570 and 1580 may be multicore processors, including first and second processor cores (i.e., processor cores 1574a and 1574b and processor cores 1584a and 1584b), although potentially many more cores may be present in the processors. Each of these processor cores can implement the strand logic 125 shown in FIG. 1A.

Still referring to FIG. 15, first processor 1570 further includes a memory controller hub (MCH) 1572 and point-to-point (P-P) interfaces 1576 and 1578. Similarly, second processor 1580 includes a MCH 1582 and P-P interfaces 1586 and 1588. As shown in FIG. 15, MCH's 1572 and 1582 couple the processors to respective memories, namely a memory 1532 and a memory 1534, which may be portions of system memory (e.g., DRAM) locally attached to the respective processors. First processor 1570 and second processor 1580 may be coupled to a chipset 1590 via P-P interconnects 1562 and 1564, respectively. As shown in FIG. 15, chipset 1590 includes P-P interfaces 1594 and 1598.

Furthermore, chipset 1590 includes an interface 1592 to couple chipset 1590 with a high performance graphics engine 1538, by a P-P interconnect 1539. In turn, chipset 1590 may be coupled to a first bus 1516 via an interface 1596. As shown in FIG. 15, various input/output (I/O) devices 1514 may be coupled to first bus 1516, along with a bus bridge 1518 which couples first bus 1516 to a second bus 1520. Various devices may be coupled to second bus 1520 including, for example, a keyboard/mouse 1522, communication devices 1526 and a data storage unit 1528 such as a disk drive or other mass storage device which may include code 1530, in one embodiment. Further, an audio I/O 1524 may be coupled to second bus 1520. Embodiments can be incorporated into other types of systems including mobile devices such as a smart cellular telephone, tablet computer, netbook, Ultrabook™′ or so forth.

Embodiments may be implemented in code and may be stored on a non-transitory storage medium having stored thereon instructions which can be used to program a system to perform the instructions. The storage medium may include, but is not limited to, any type of disk including floppy disks, optical disks, solid state drives (SSDs), compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), magnetic or optical cards, or any other type of media suitable for storing electronic instructions.

The following clauses and/or examples pertain to further embodiments

In one example, a processor for processing strands includes a plurality of cores. Each core can include strand logic to: for each strand of a plurality of strands, fetch an instruction group uniquely associated with the strand, wherein the instruction group is one of a plurality of instruction groups, wherein the plurality of instruction groups is obtained by dividing instructions of an application program according to instruction criticality; and retire the instruction group in an original order of the application program.

In an example, a fetch order within a strand is restricted to the original order of the application program, and wherein a fetch order across multiple strands is not restricted to the original order of the application program.

In an example, the strand logic is further to allocate the instruction group to a first partition of a window buffer, wherein the window buffer is divided into a plurality of partitions associated with the plurality of strands.

In an example, each core comprises a plurality of processing ways, and where each processing way of the plurality of processing ways is to execute a unique one of the plurality of strands.

In an example, each instruction group of plurality of instruction groups is associated with a different level of instruction criticality.

In an example, the plurality of instruction groups is generated by a strand compiler, wherein the strand compiler estimates a criticality level of each instruction in the application program. In an example, the strand compiler compiles the application program into binary code that includes information indicating the criticality level of each instruction in the application program, and wherein the strand logic fetches the instruction group using the information indicating the criticality level.

In another example, a method for processing strands includes fetching a first instruction subset to be executed in a first strand of a plurality of strands of a processor core, wherein the first instruction subset is one of a plurality of instruction subsets of an application and is associated with a first level of instruction criticality, wherein each of the plurality of instruction subsets is executed in a unique strand of the plurality of strands and is associated with a unique level of instruction criticality; executing instructions of the first instruction subset in the first strand of the plurality of strands; and retiring, in a program order of the application, instructions of the first instruction subset.

In an example, the method also includes fetching a second instruction subset to be executed in a second strand of the plurality of strands, wherein the second instruction subset is included in the plurality of instruction subsets of the application and is associated with a second level of instruction criticality; executing instructions of the second instruction subset in the second strand of the plurality of strands; and retiring, in the program order of the application, instructions of the second instruction subset.

In an example, the method also includes allocating the first instruction subset to a first partition of a window buffer, wherein the window buffer is divided into a plurality of partitions associated with the plurality of strands. In an example, each of the plurality of partitions includes an equal number of entries, and wherein a percentage of instructions assigned to each instruction subset increases as the level of instruction criticality of the instruction subset decreases. In an example, the window buffer is one selected from a reorder buffer, a load buffer, and a store buffer.

In an example, the method also includes determining, by a strand compiler, criticality information for each instruction of the application; and assigning each instruction to an instruction subset based on the criticality information. In an example, the method also includes compiling, by the strand compiler, the application program into binary code using the criticality information for each instruction of the application.

In another example, a machine readable medium has stored thereon data, which if used by at least one machine, causes the at least one machine to fabricate at least one integrated circuit to perform the method of any of the above examples.

In another example, an apparatus for processing instructions is configured to perform the method of any of the above examples.

In another example, a system for processing strands includes a processor and a memory coupled to the processor and storing instructions. The instructions are executable by the processor to: determine criticality information for each instruction in an application program; assign, based on the criticality information, each instruction to one of a plurality of instruction groups; determine data dependencies between the plurality of instruction groups; and transform the application program into a compiled program using the criticality information and the data dependencies.

In an example, the processor includes a window buffer, wherein the window buffer is divided into a plurality of partitions. In an example, the each one of plurality of partitions is uniquely associated with one of the plurality of instruction groups. In an example, each one of the plurality of partitions includes an equal number of entries, and wherein a percentage of instructions assigned to each instruction group increases as a level of criticality of the instruction group decreases. In an example, the window buffer is one selected from a reorder buffer, a load buffer, and a store buffer.

In an example, the compiled program includes, for each instruction, information indicating an original program order of the instruction.

In an example, each strand of the plurality of strands is to execute a unique instruction group of the plurality of instruction groups.

In an example, the processor is to: fetch and allocate each instruction in strand order; and retire each instruction in program order across the plurality of strands.

Understand that various combinations of the above examples are possible.

Embodiments may be used in many different types of systems. For example, in one embodiment a communication device can be arranged to perform the various methods and techniques described herein. Of course, the scope of the present invention is not limited to a communication device, and instead other embodiments can be directed to other types of apparatus for processing instructions, or one or more machine readable media including instructions that in response to being executed on a computing device, cause the device to carry out one or more of the methods and techniques described herein.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A processor comprising:
a plurality of cores, each core including strand logic to:
for each strand of a plurality of strands, fetch an instruction group uniquely associated with the strand, wherein the instruction group is one of a plurality of instruction groups, wherein the plurality of instruction groups is obtained by dividing instructions of an application program according to instruction criticality; and
retire the instruction group in an original order of the application program.

2. The processor of claim 1, wherein a fetch order within a strand is restricted to the original order of the application program, and wherein a fetch order across multiple strands is not restricted to the original order of the application program.

3. The processor of claim 1, wherein the strand logic is further to allocate the instruction group to a first partition of a window buffer, wherein the window buffer is divided into a plurality of partitions associated with the plurality of strands.

4. The processor of claim 1, wherein each core comprises a plurality of processing ways, and where each processing way of the plurality of processing ways is to execute a unique one of the plurality of strands.

5. The processor of claim 1, wherein each instruction group of plurality of instruction groups is associated with a different level of instruction criticality.

6. The processor of claim 1, wherein the plurality of instruction groups is generated by a strand compiler, wherein the strand compiler estimates a criticality level of each instruction in the application program.

7. The processor of claim 6, wherein the strand compiler compiles the application program into binary code that includes information indicating the criticality level of each instruction in the application program, and wherein the strand logic fetches the instruction group using the information indicating the criticality level.

8. A method comprising:
fetching a first instruction subset to be executed in a first strand of a plurality of strands of a processor core, wherein the first instruction subset is one of a plurality of instruction subsets of an application and is associated with a first level of instruction criticality, wherein each of the plurality of instruction subsets is executed in a unique strand of the plurality of strands and is associated with a unique level of instruction criticality;
executing instructions of the first instruction subset in the first strand of the plurality of strands; and
retiring, in a program order of the application, instructions of the first instruction subset.

9. The method of claim 8, further comprising:
fetching a second instruction subset to be executed in a second strand of the plurality of strands, wherein the second instruction subset is included in the plurality of instruction subsets of the application and is associated with a second level of instruction criticality;
executing instructions of the second instruction subset in the second strand of the plurality of strands; and
retiring, in the program order of the application, instructions of the second instruction subset.

10. The method of claim 8, further comprising:
allocating the first instruction subset to a first partition of a window buffer, wherein the window buffer is divided into a plurality of partitions associated with the plurality of strands.

11. The method of claim 10, wherein each of the plurality of partitions includes an equal number of entries, and wherein a percentage of instructions assigned to each instruction subset increases as the level of instruction criticality of the instruction subset decreases.

12. The method of claim 8, further comprising:
determining, by a strand compiler, criticality information for each instruction of the application; and
assigning each instruction to an instruction subset based on the criticality information.

13. The method of claim 12, further comprising:
compiling, by the strand compiler, the application program into binary code using the criticality information for each instruction of the application.

14. A system comprising:
a processor; and
a memory coupled to the processor and storing instructions, the instructions executable by the processor to:
determine criticality information for each instruction in an application program;
assign, based on the criticality information, each instruction to one of a plurality of instruction groups;
determine data dependencies between the plurality of instruction groups; and
transform the application program into a compiled program using the criticality information and the data dependencies.

15. The system of claim 14, wherein the processor includes a window buffer, wherein the window buffer is divided into a plurality of partitions.

16. The system of claim 15, wherein the each one of plurality of partitions is uniquely associated with one of the plurality of instruction groups.

17. The system of claim 15, wherein each one of the plurality of partitions includes an equal number of entries, and wherein a percentage of instructions assigned to each instruction group increases as a level of criticality of the instruction group decreases.

18. The system of claim 14, wherein the compiled program includes, for each instruction, information indicating an original program order of the instruction.

19. The system of claim 14, wherein each strand of the plurality of strands is to execute a unique instruction group of the plurality of instruction groups.

20. The system of claim 14, wherein the processor is to:
fetch and allocate each instruction in strand order; and
retire each instruction in program order across the plurality of strands.
